(19) United States
(12) Patent Application Publication
(10) Pub. No.: US 2014/0360567 A1
(43) Pub. Date: Dec. 11, 2014

(54) BACK CONTACT SOLAR CELLS USING ALUMINUM-BASED ALLOY METALLIZATION

(71) Applicant: Solexel, Inc., (US)

(72) Inventors: Sean M. Seutter, San Jose, CA (US); Mehrdad M. Moslehi, Los Altos, CA (US); Anand Deshpande, Milpitas, CA (US); Virendra V. Rana, Los Gatos, CA (US); Pawan Kapur, Burlingame, CA (US); Karl-Josef Kramer, San Jose, CA (US); Anthony Calcaterra, Milpitas, CA (US); David Dutton, Milpitas, CA (US); Takao Yonehara, Milpitas, CA (US)

(73) Assignee: Solexel, Inc., Milpitas, CA (US)

(21) Appl. No.: 13/853,031

(22) Filed: Mar. 28, 2013

Related U.S. Application Data
(63) Continuation-in-part of application No. 13/204,626, filed on Aug. 5, 2011.
Application No. 13/204,626 is a continuation-in-part of application No. 13/807,631.
Application No. 13/807,631 is a continuation-in-part of application No. 13/731,112, filed on Dec. 31, 2012.
(60) Provisional application No. 61/617,023, filed on Mar. 28, 2012.
(60) Provisional application No. 61/725,981, filed on Nov. 13, 2012.

(51) Int. Cl. H01L 31/0224; H01L 31/0232; H01B 1/02; H01L 31/18

(52) U.S. Cl. CPC H01L 31/022458; H01L 31/18; H01L 31/02327; H01B 1/023
USPC 136/256; 438/72; 420/548

(57) ABSTRACT

Methods and structures for photovoltaic back contact solar cells having multi-level metallization with at least one aluminum-silicon alloy metallization layer are provided.

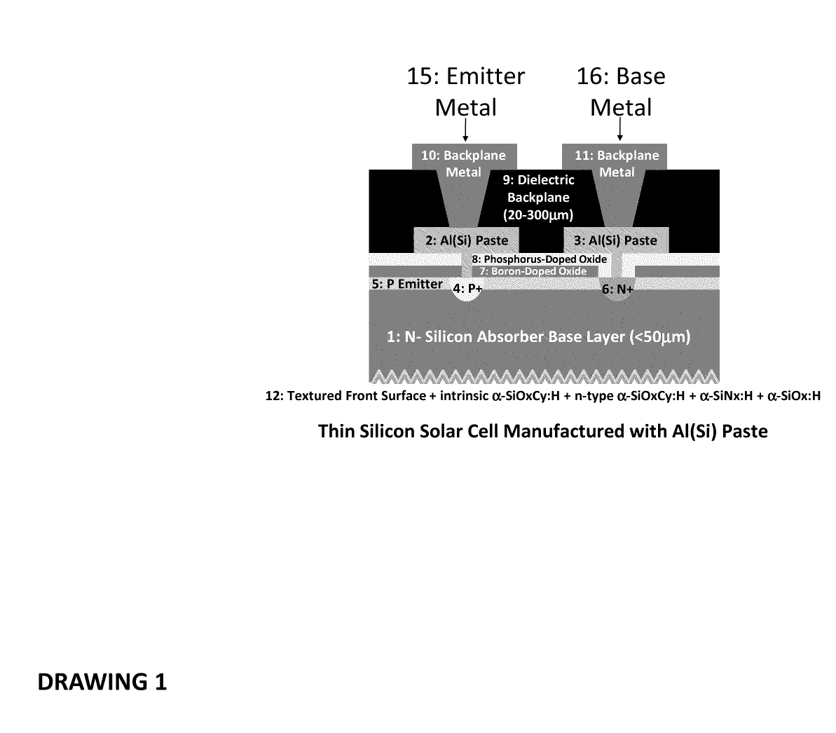

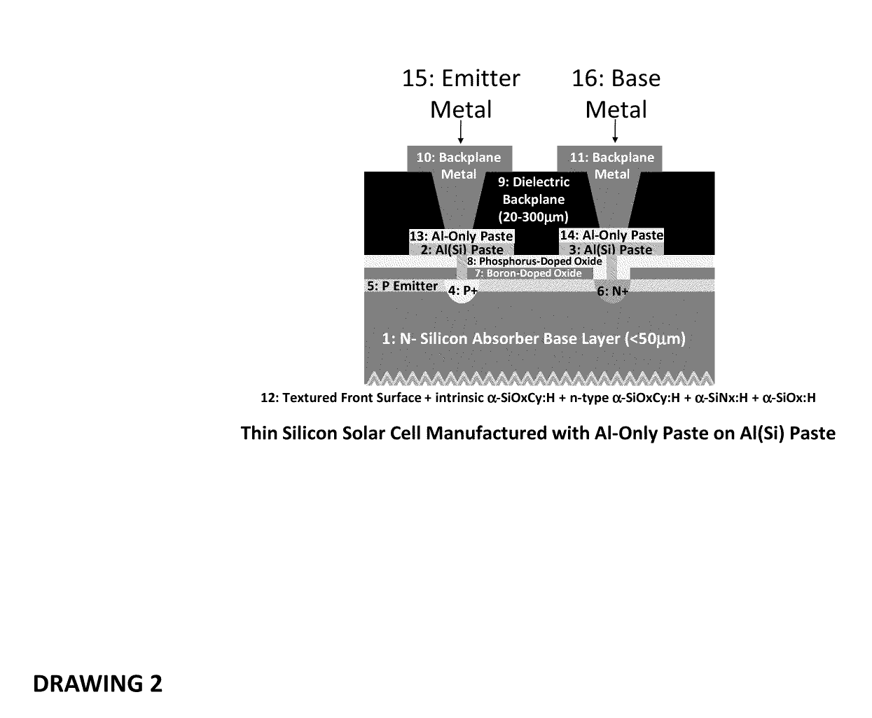

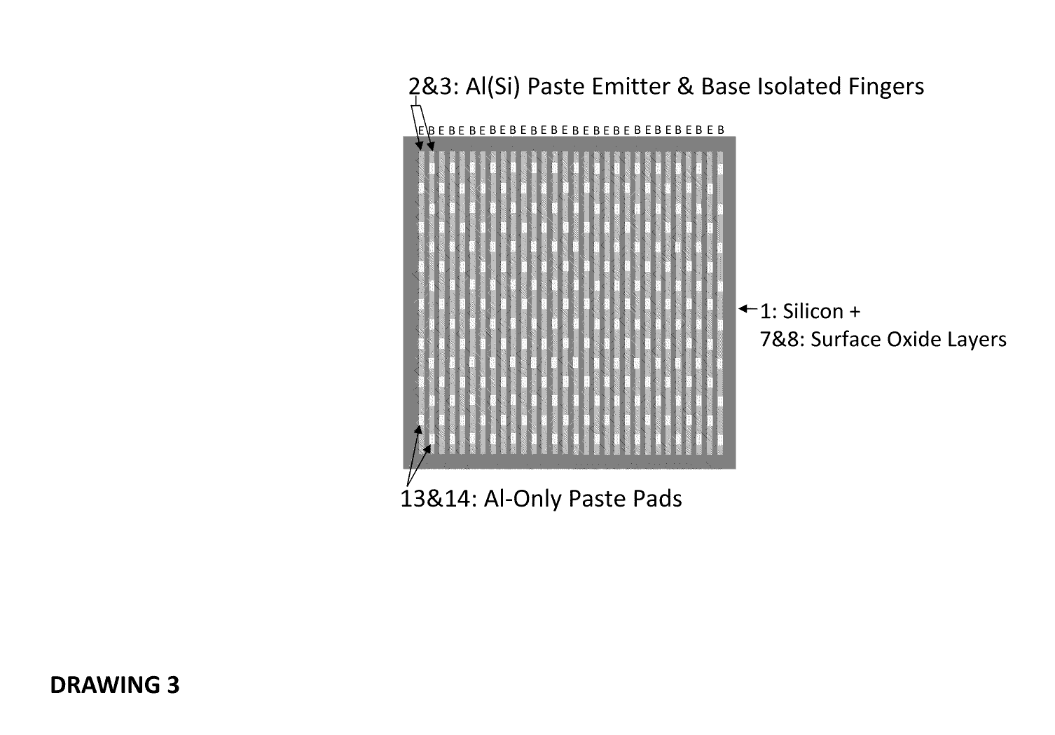

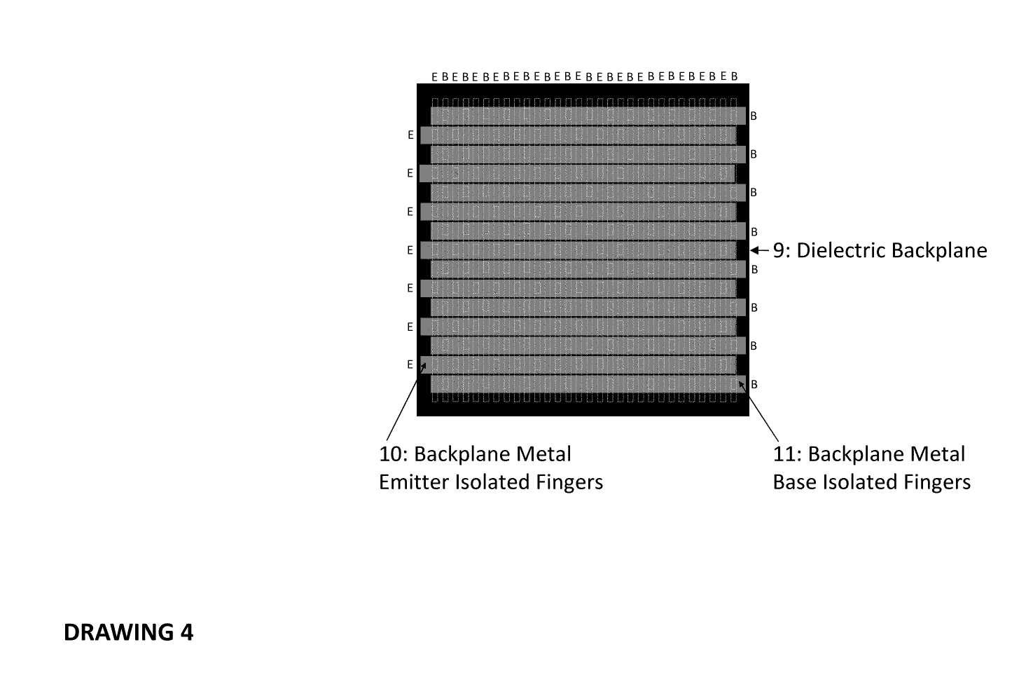

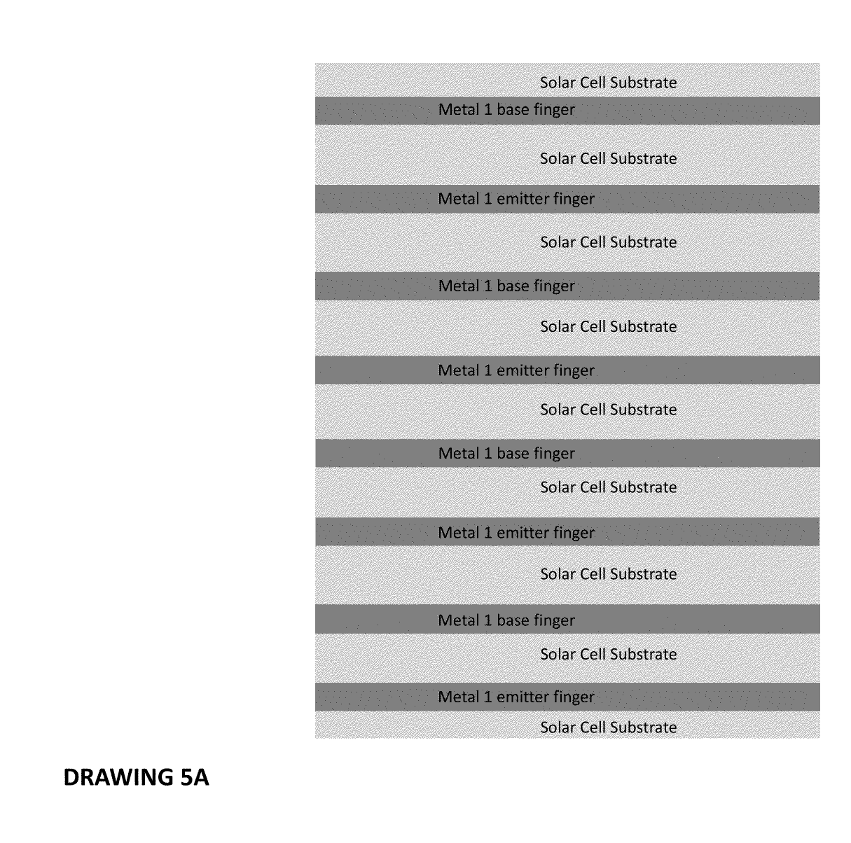

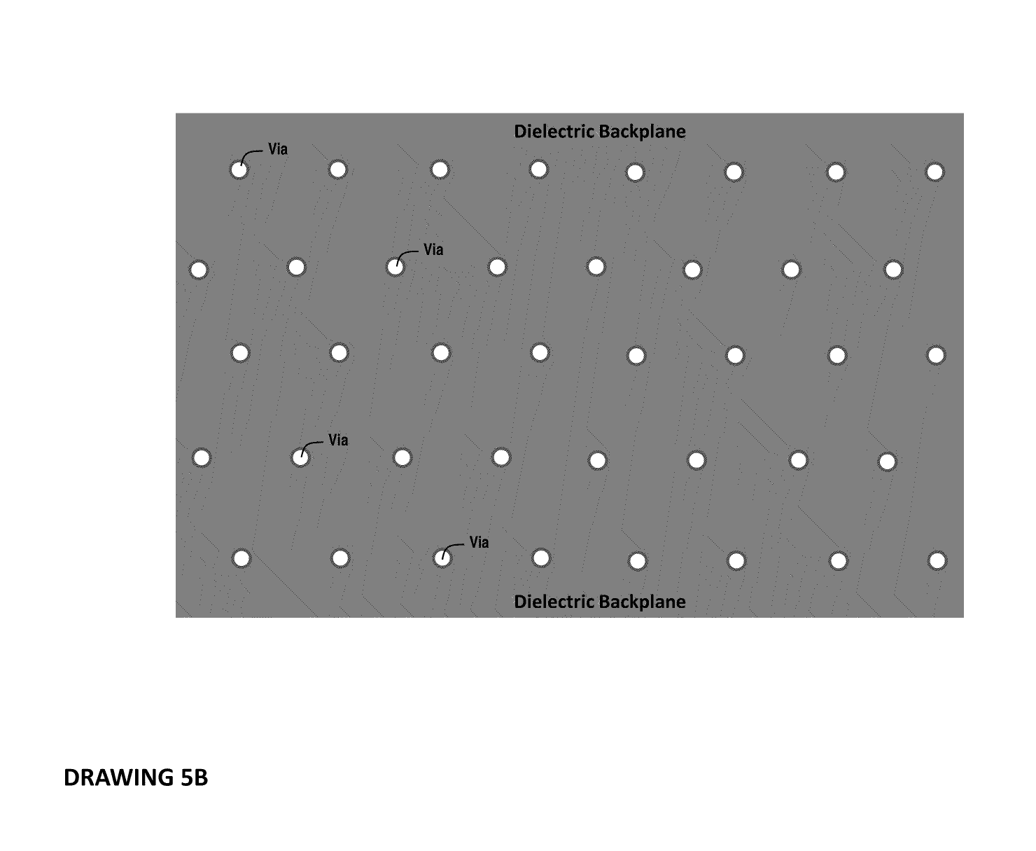

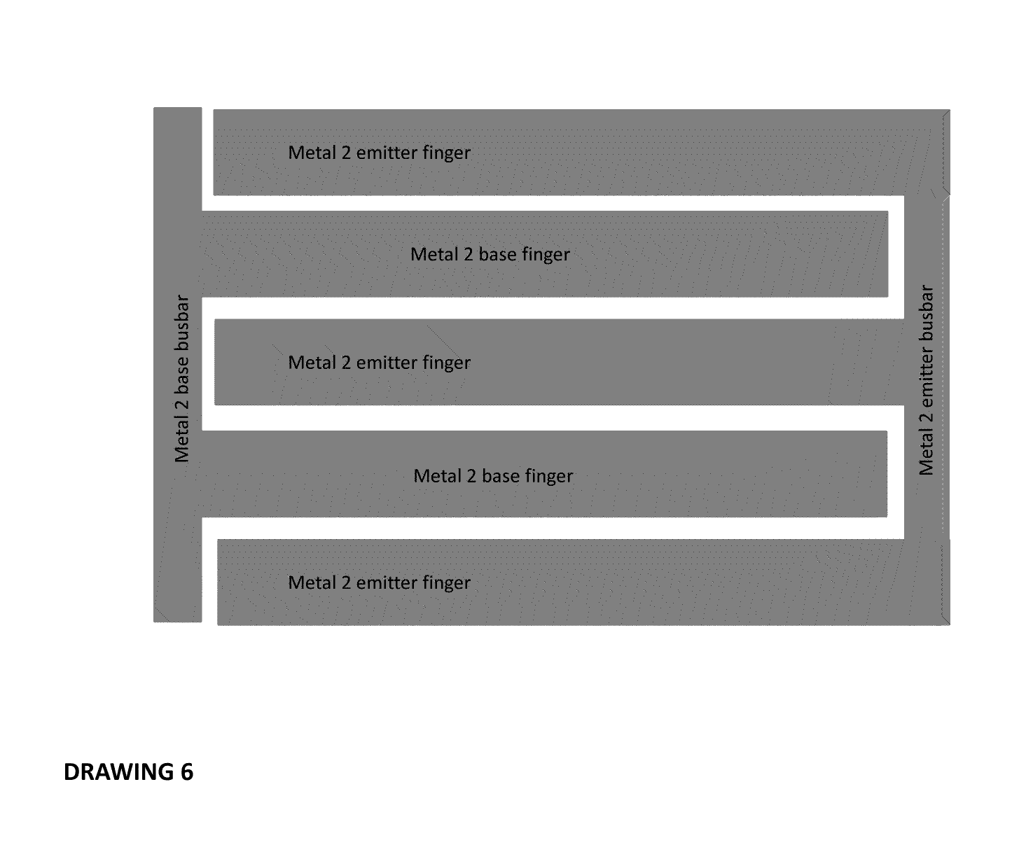

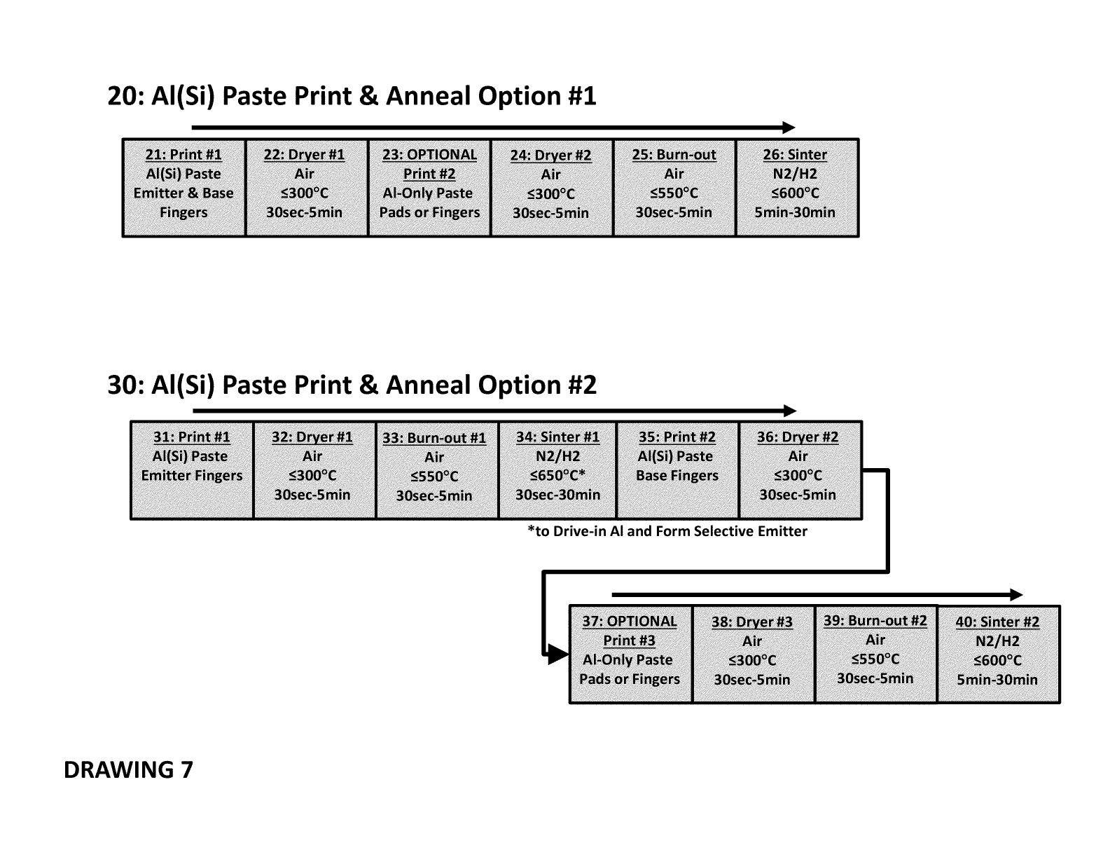

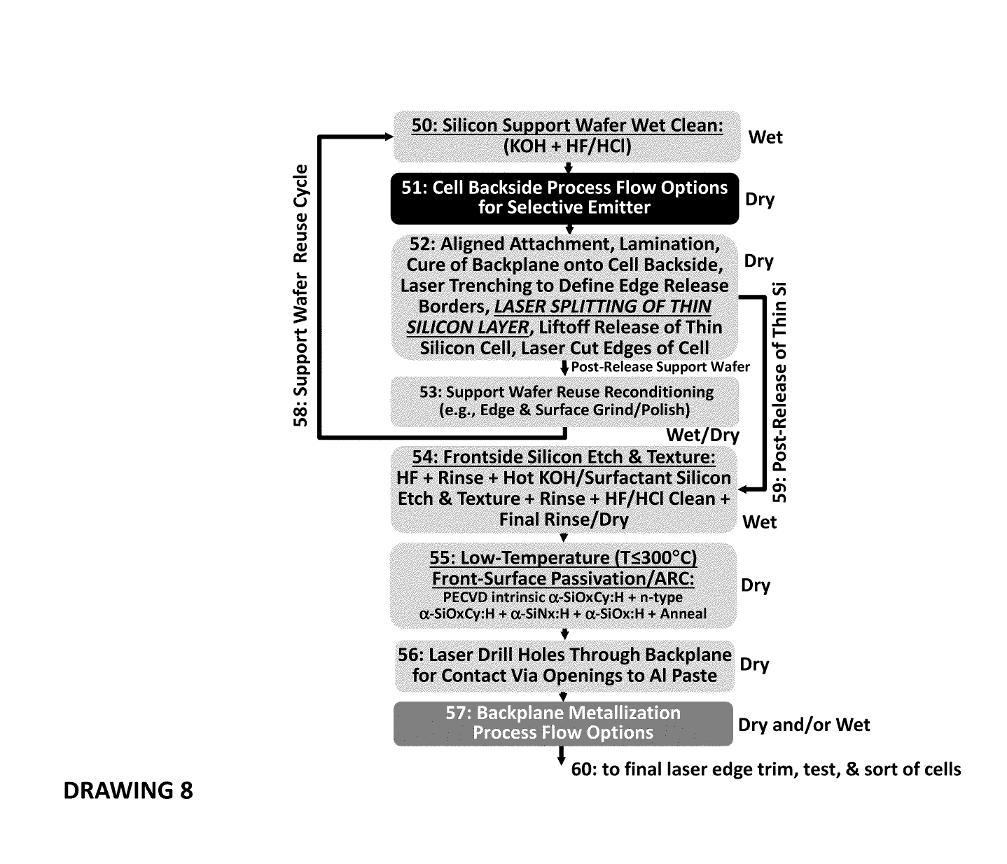

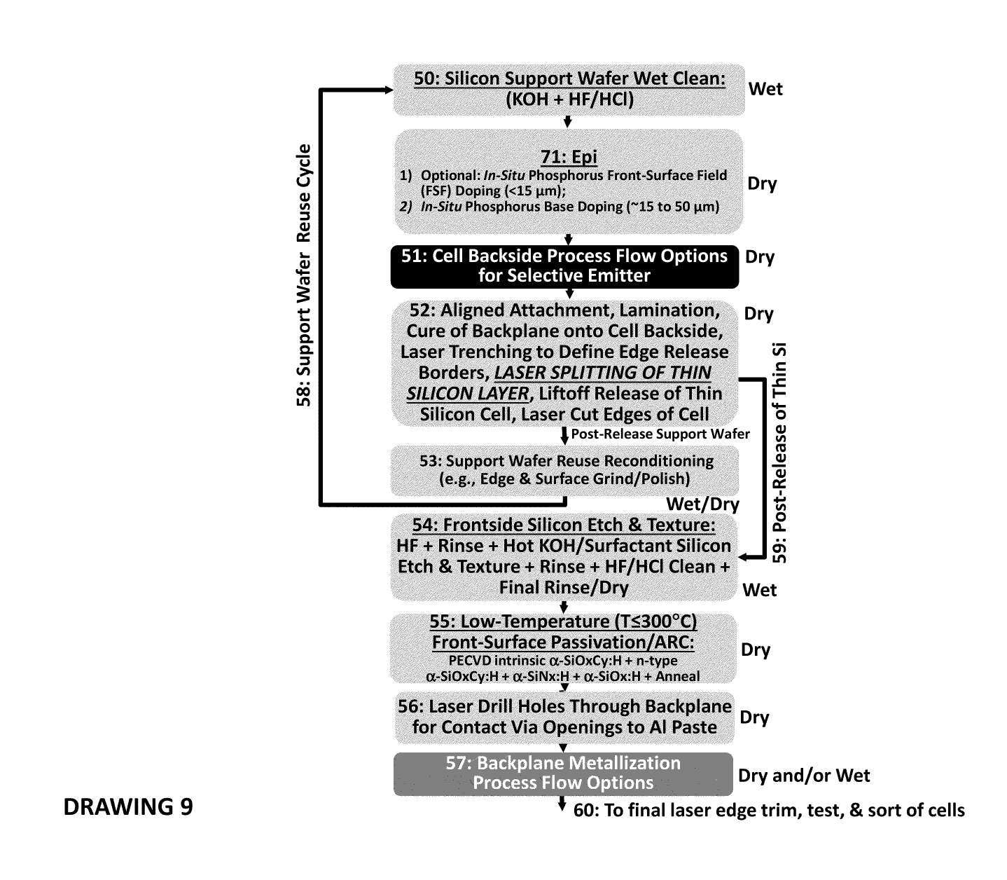

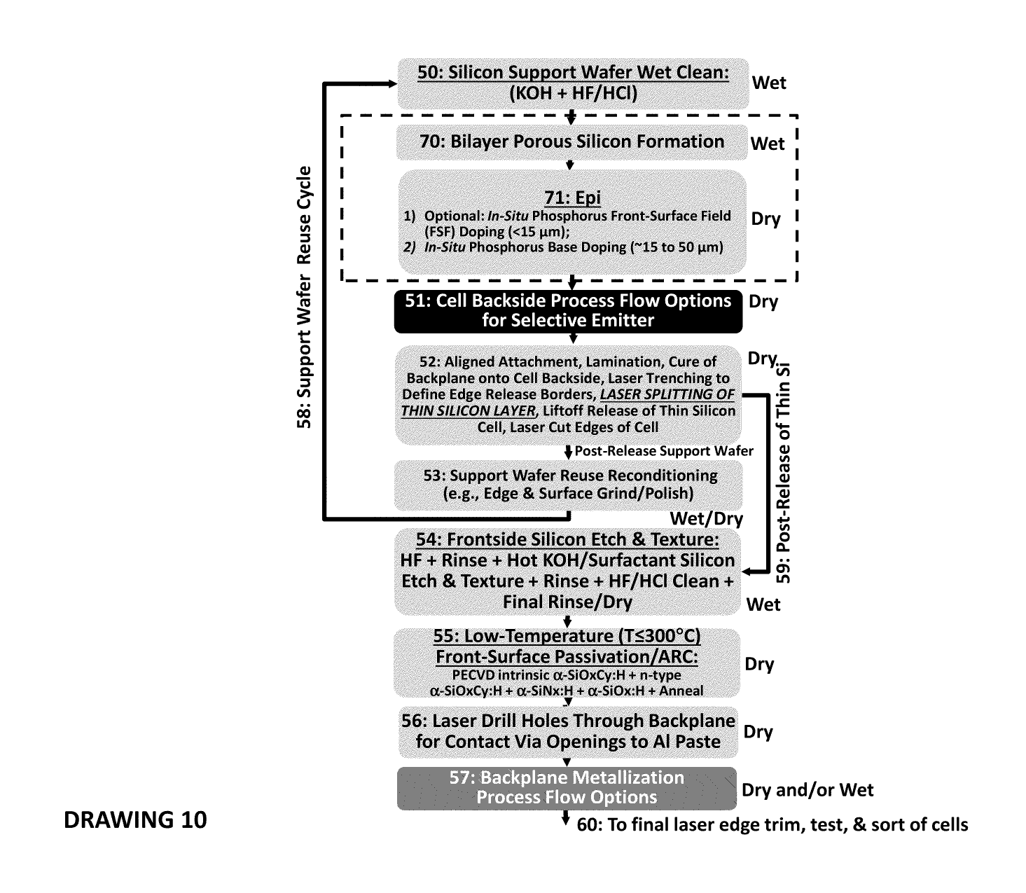

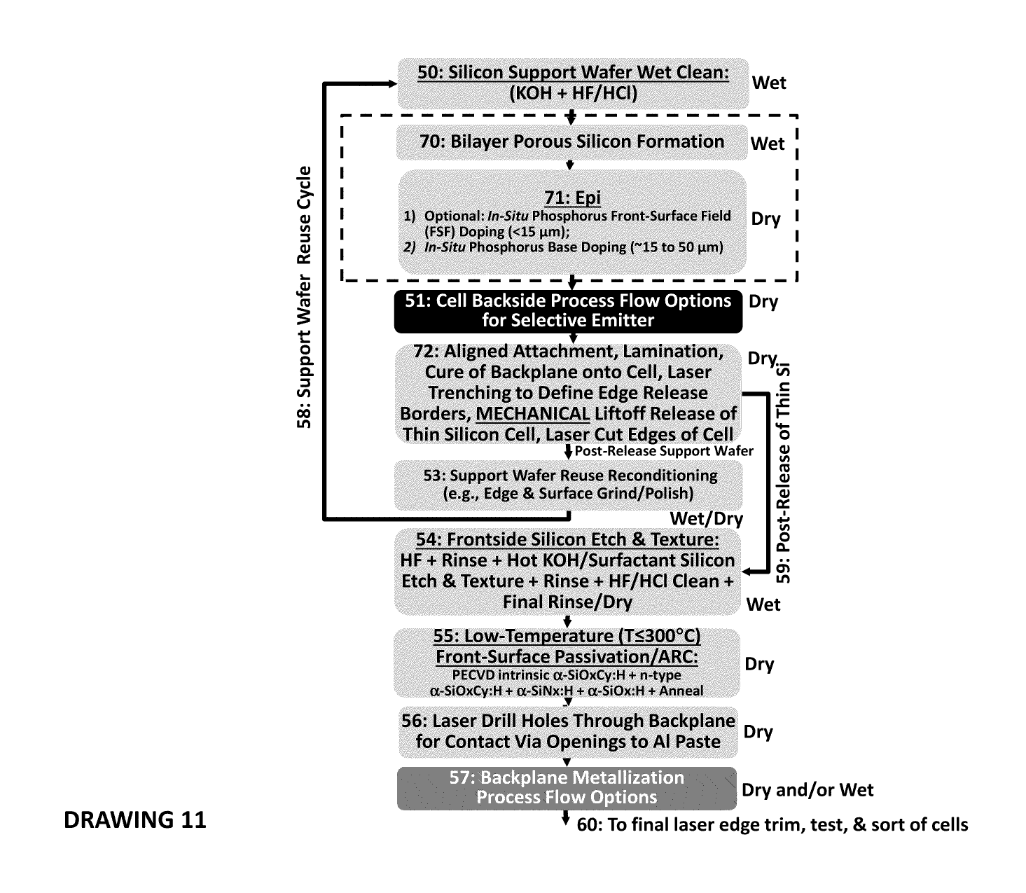

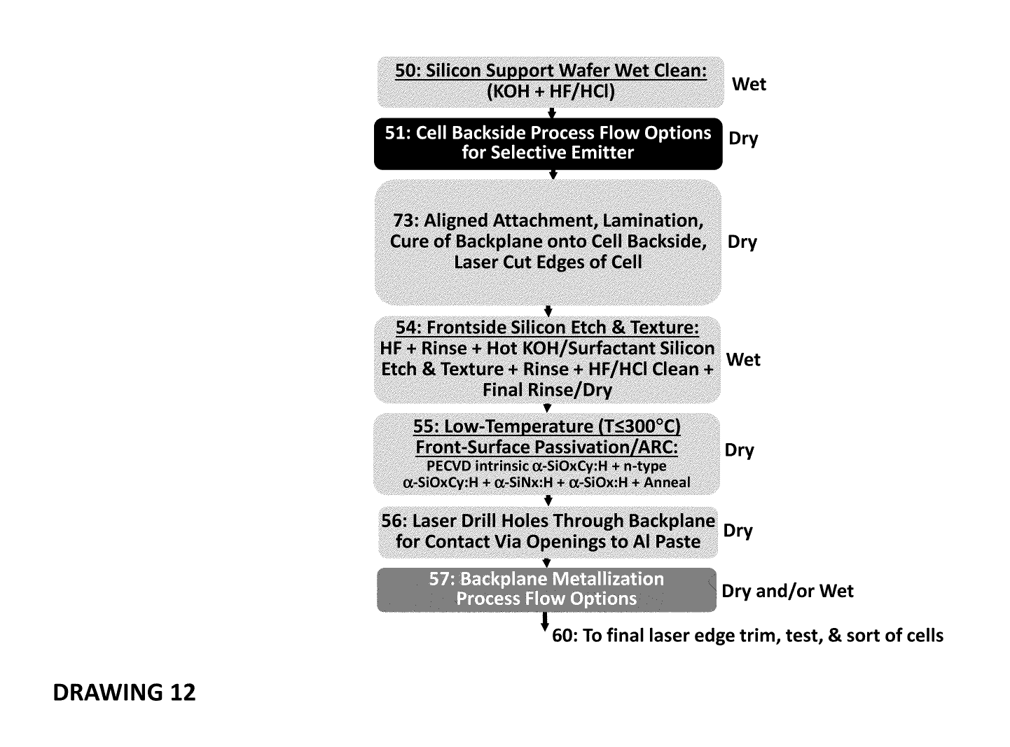

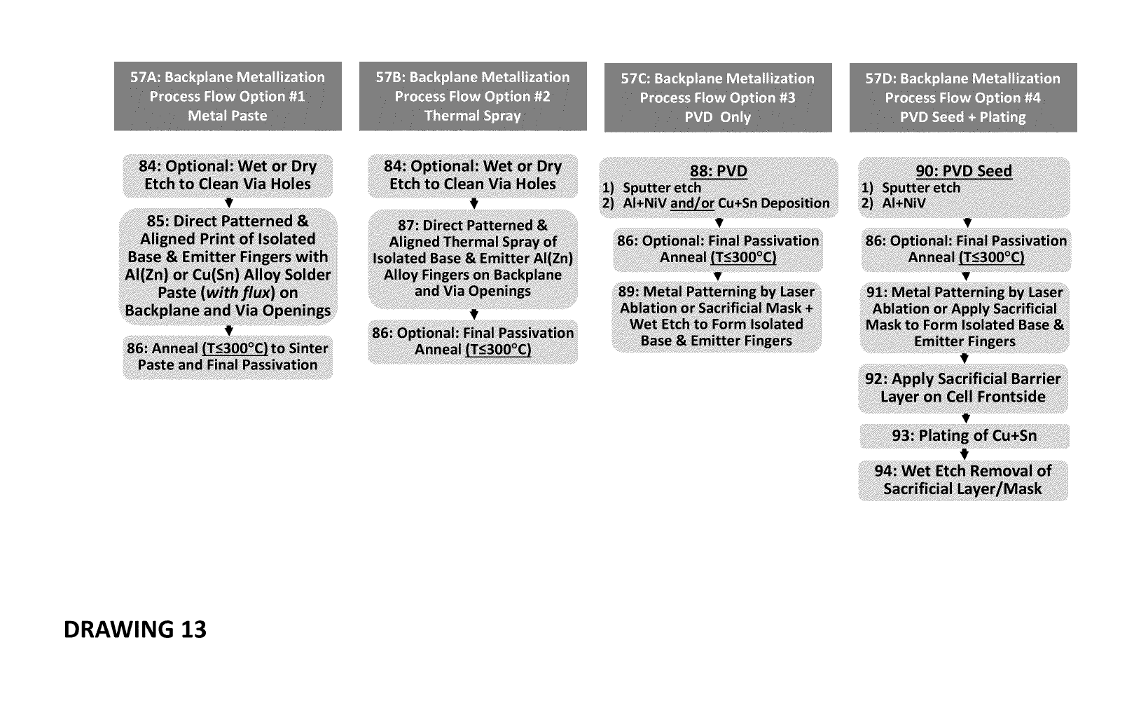

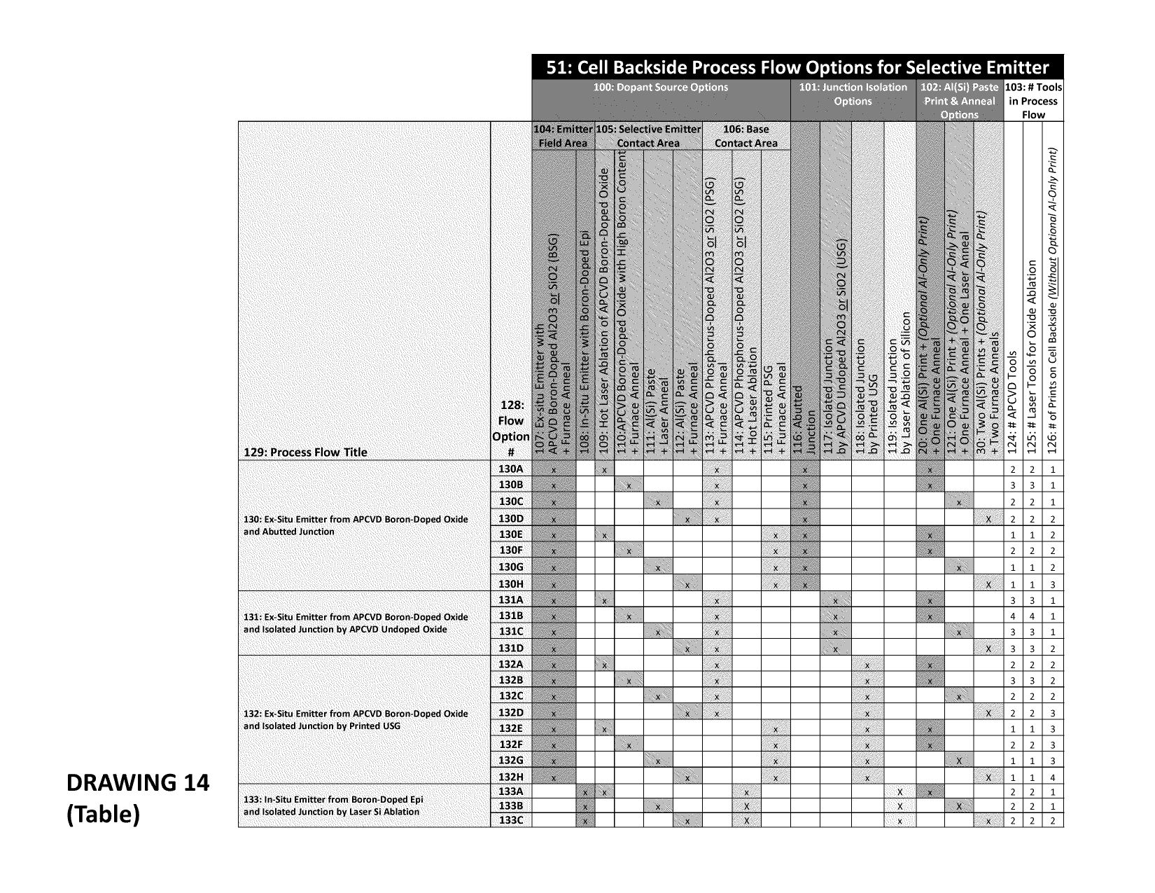

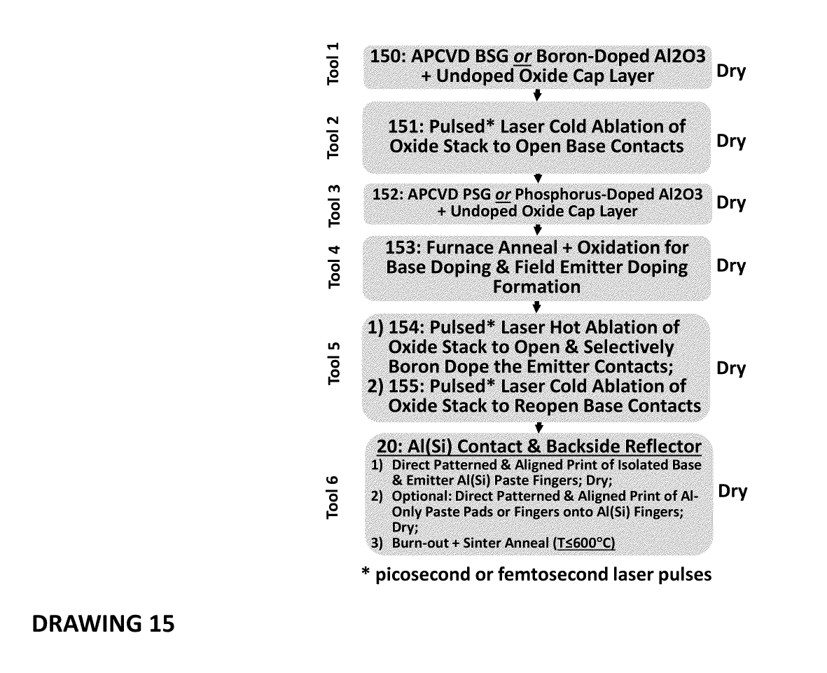

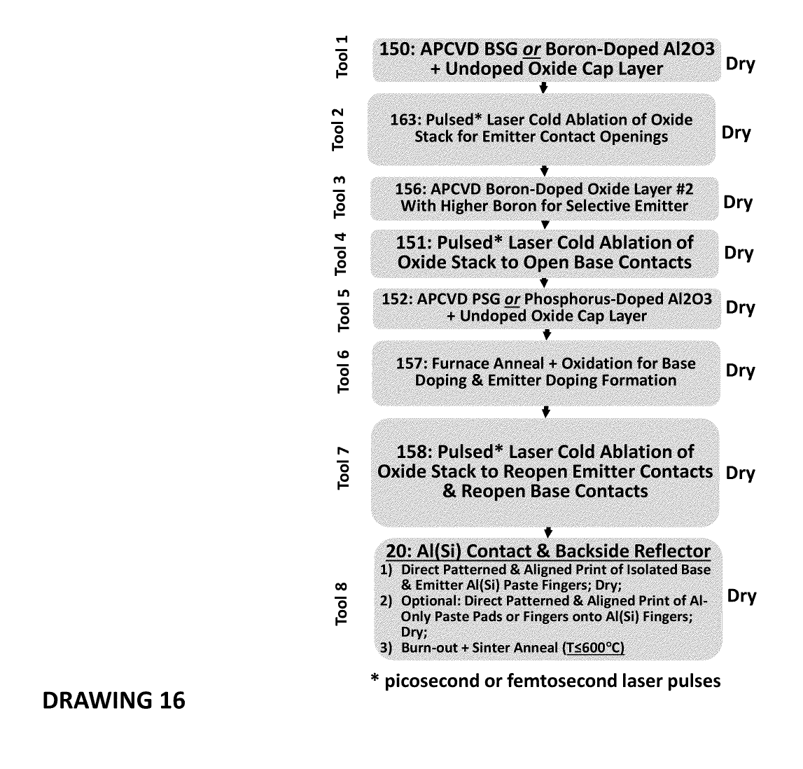

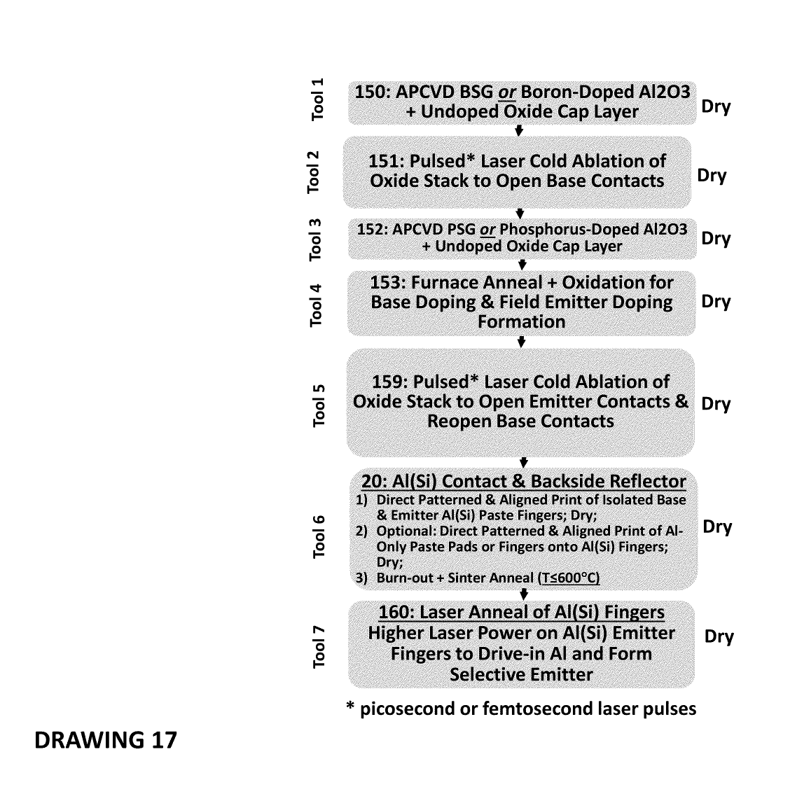

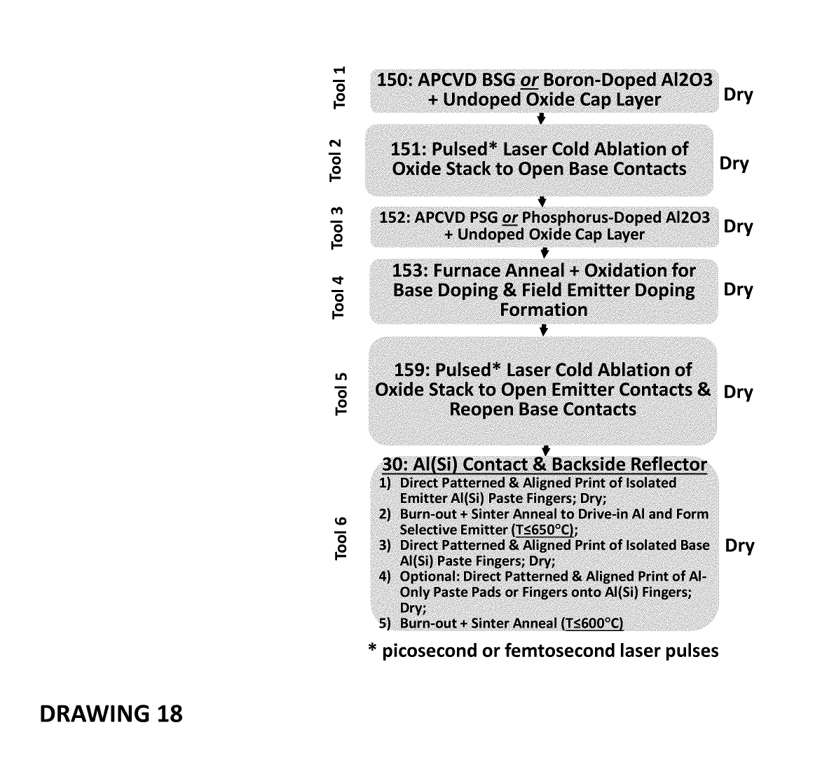

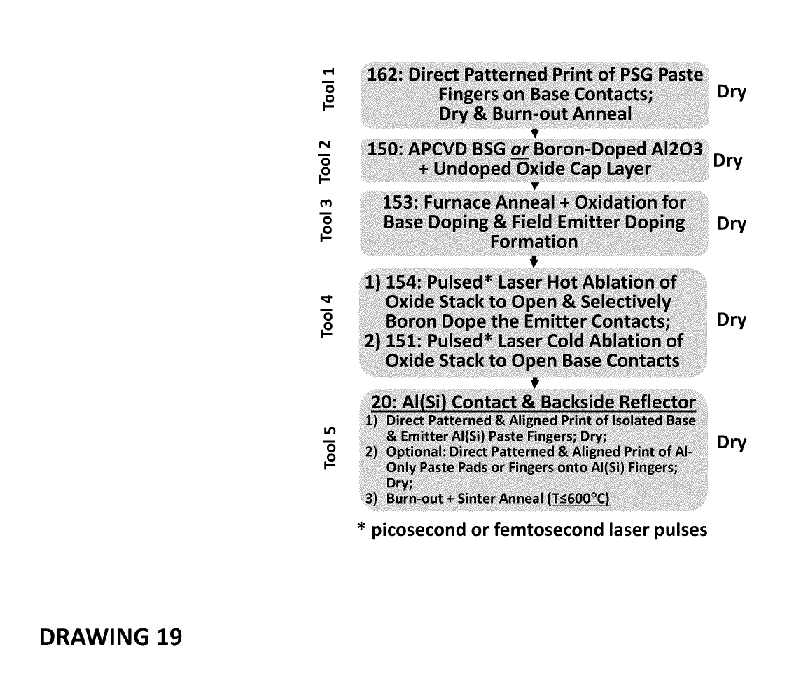

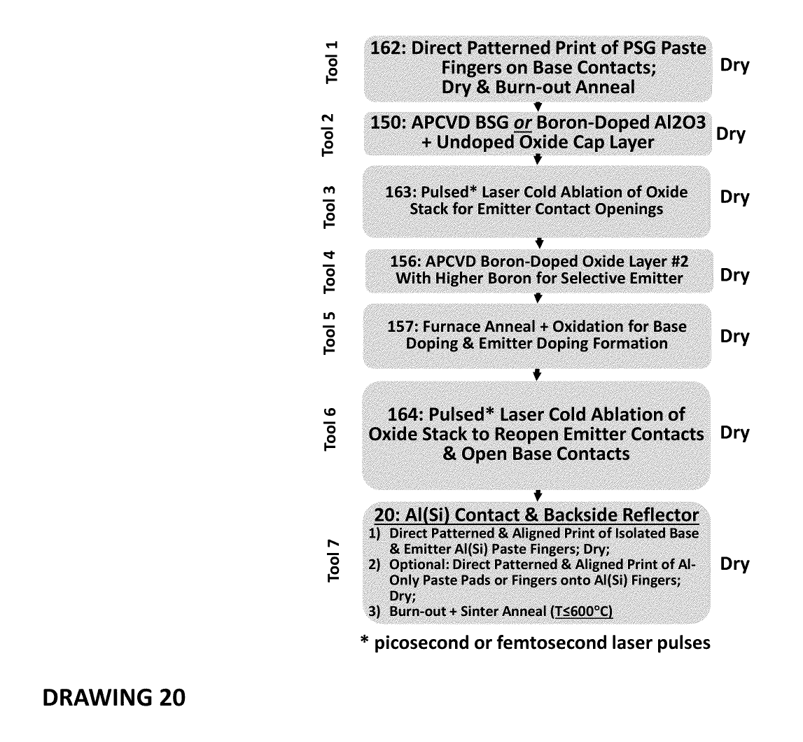

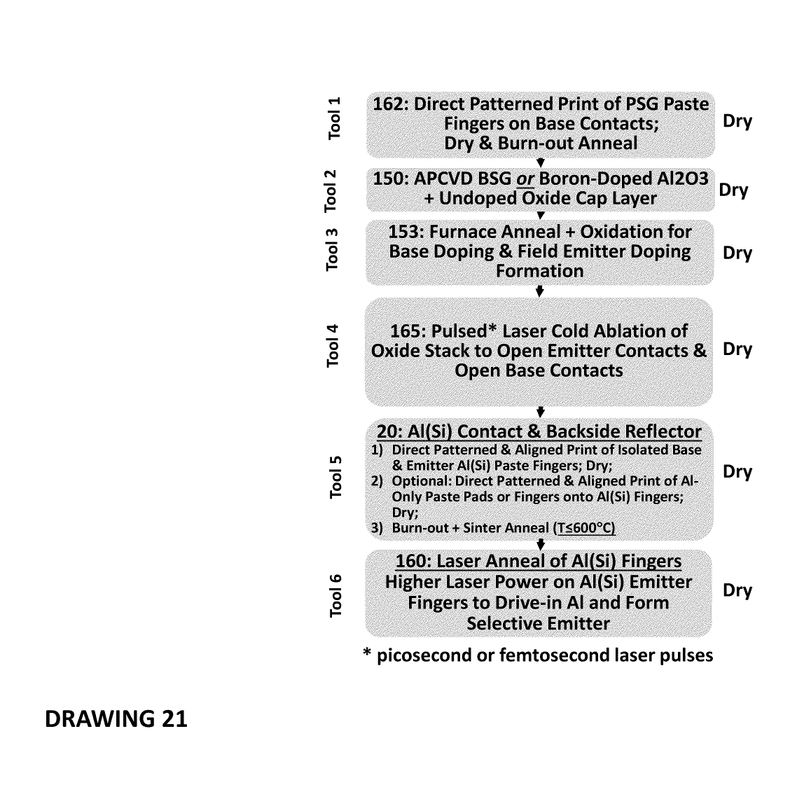

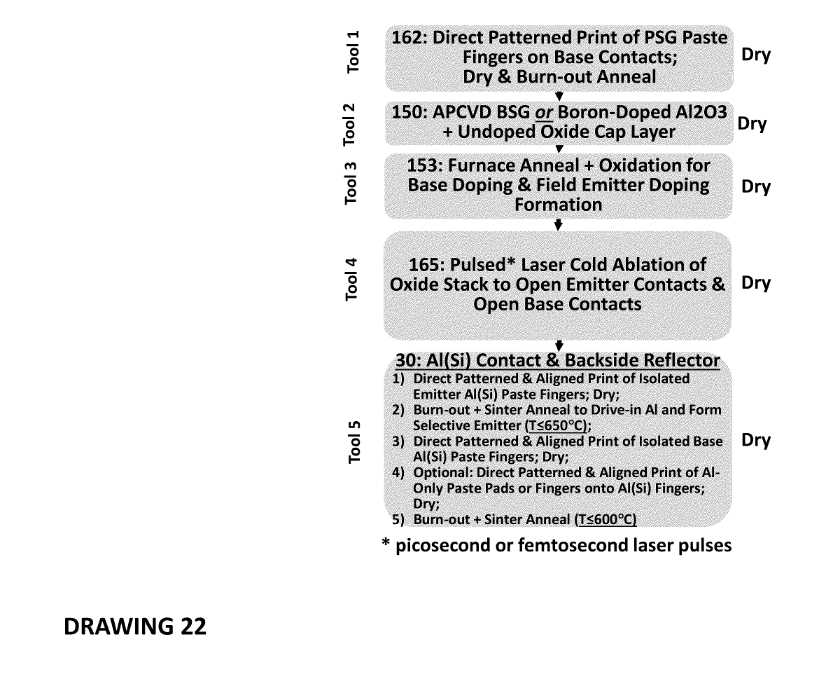

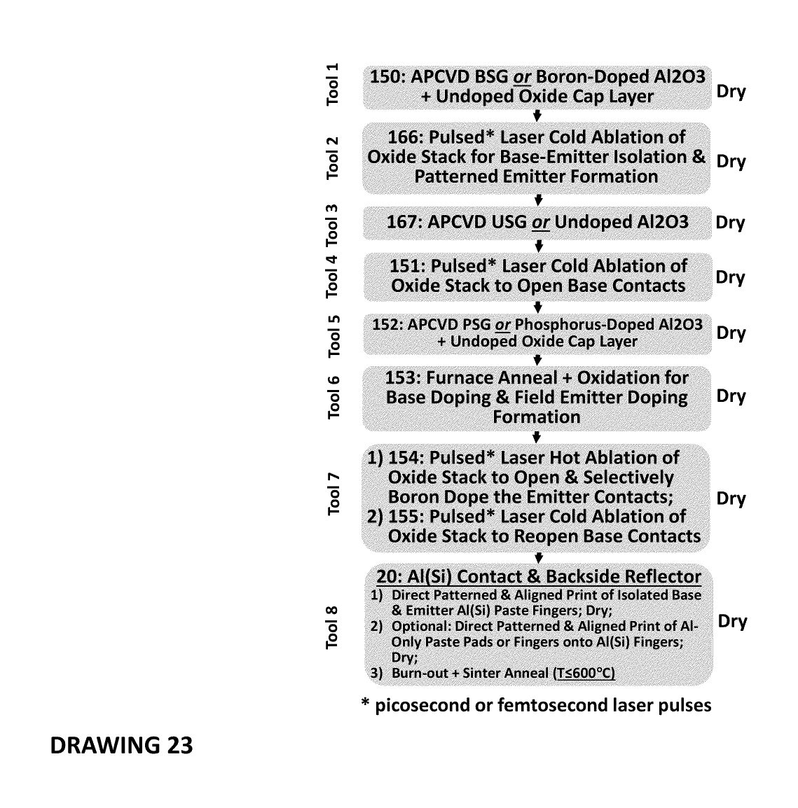

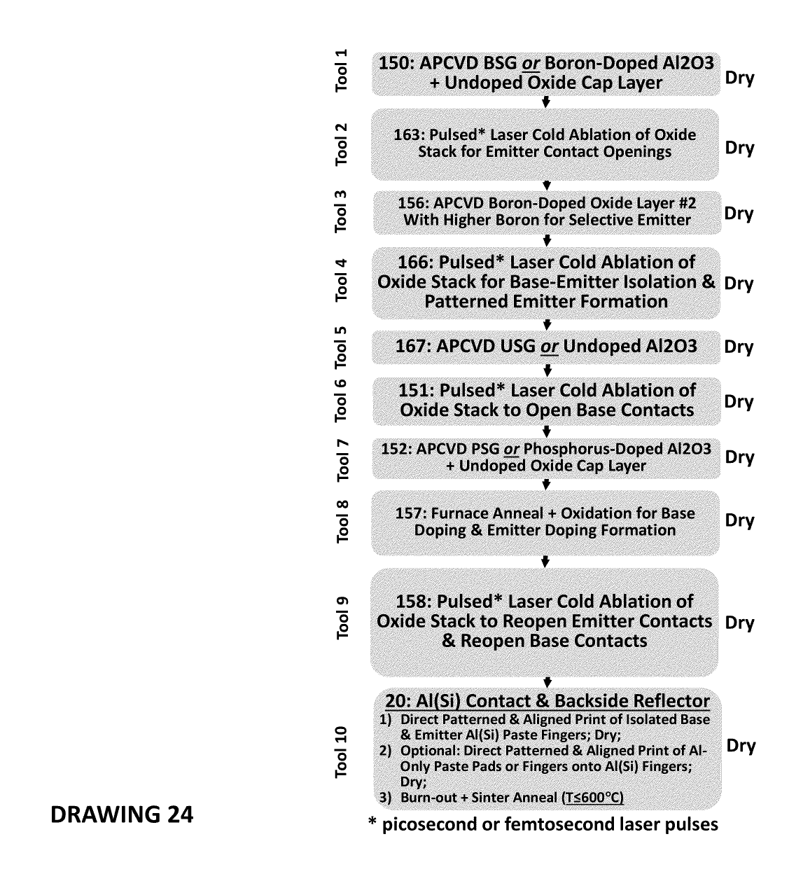

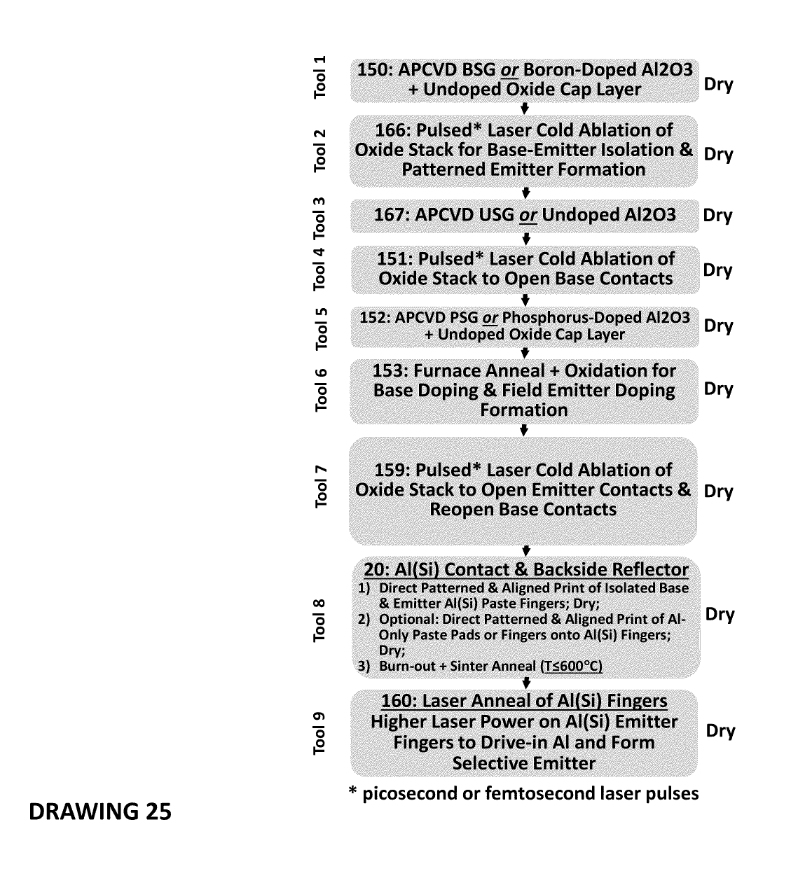

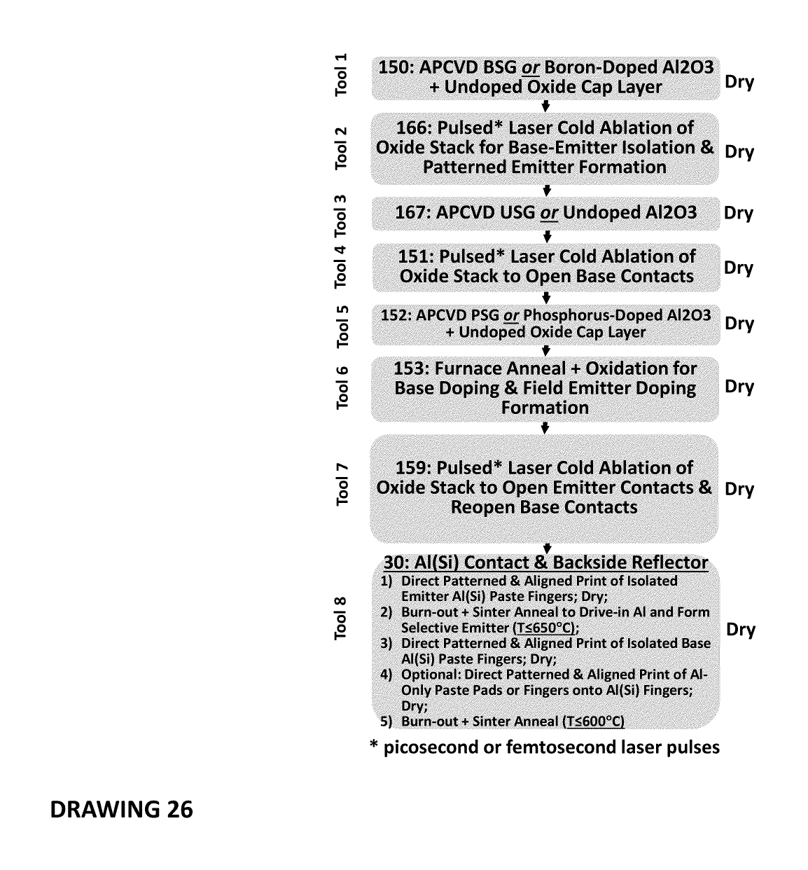

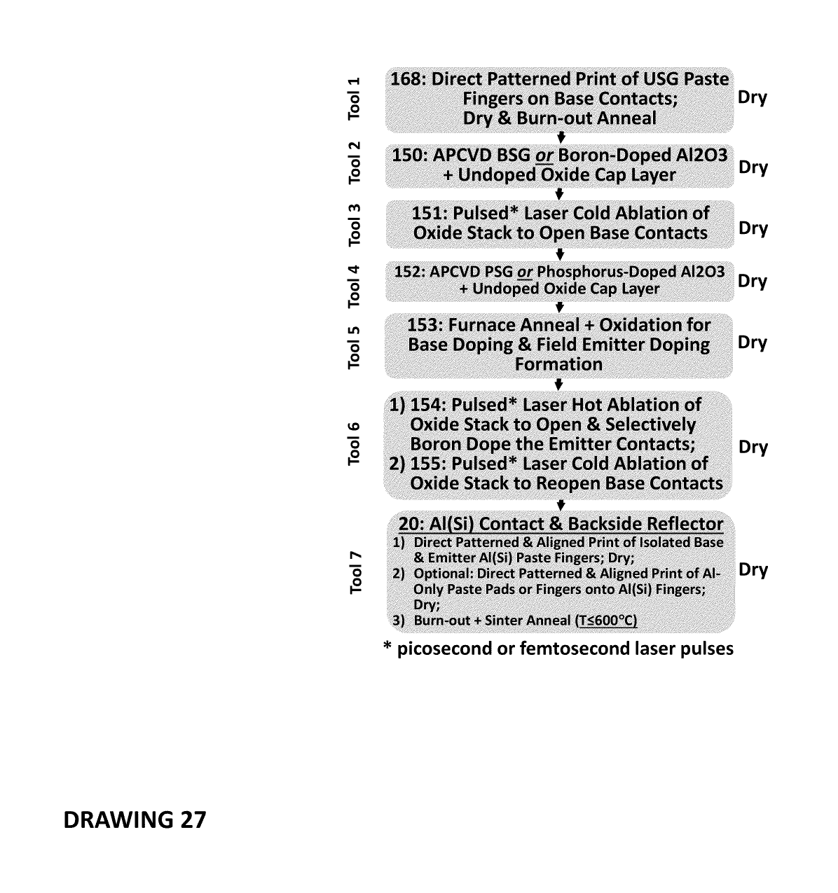

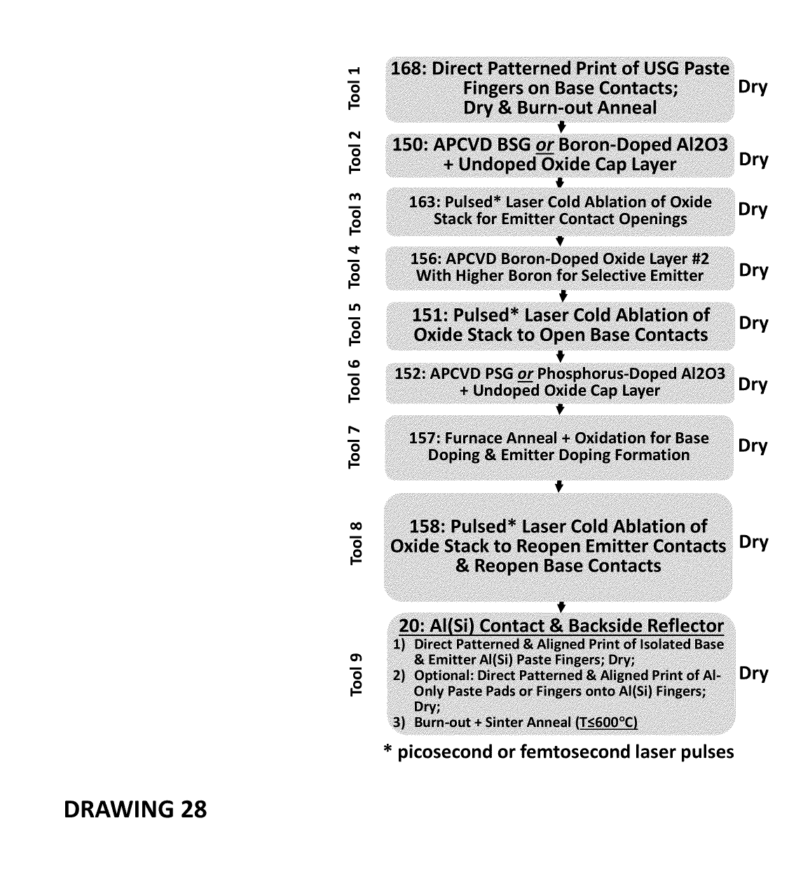

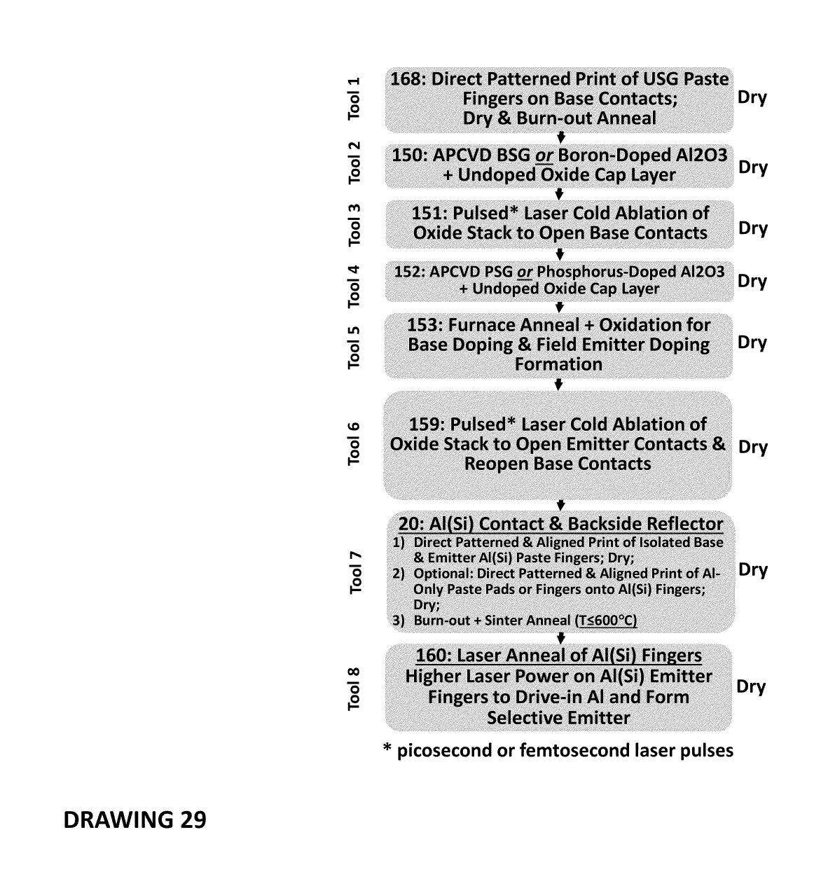

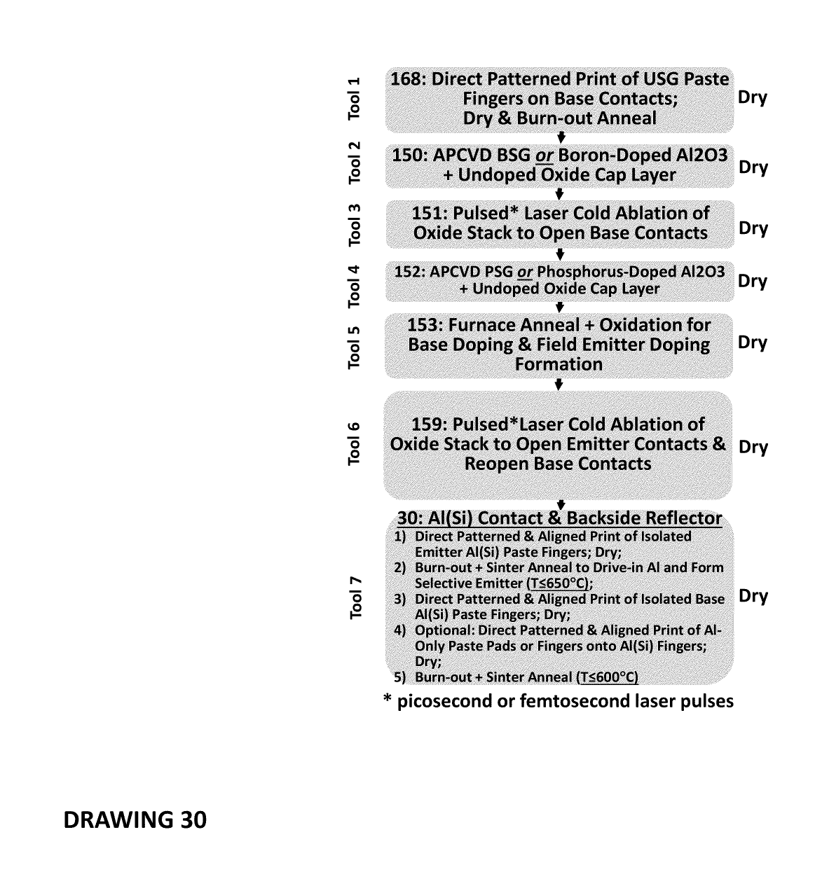

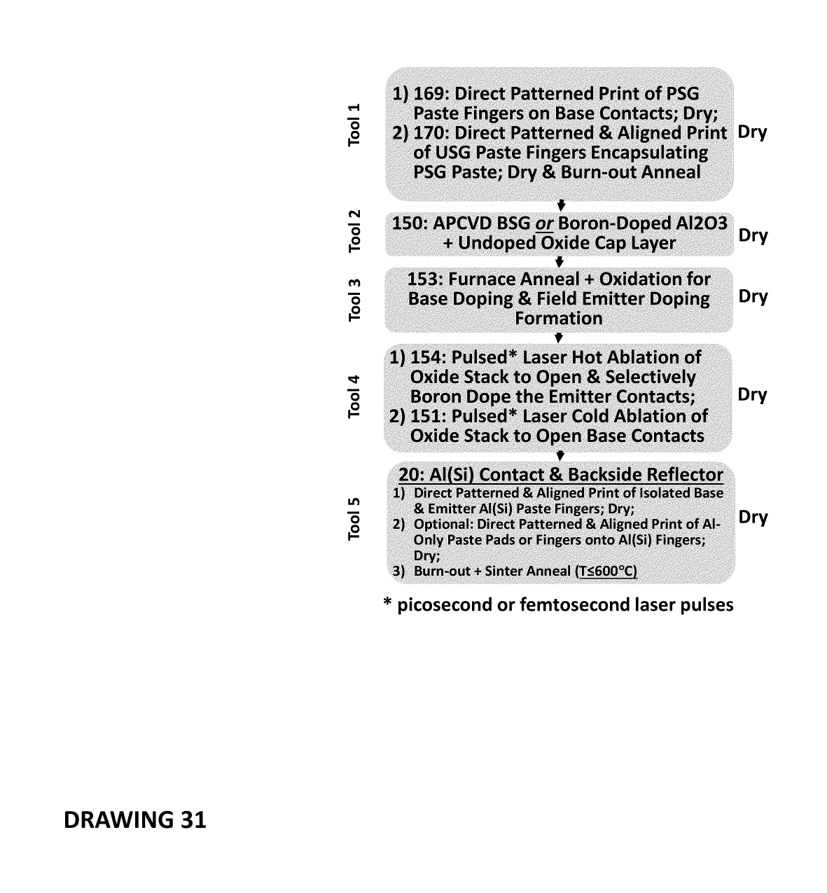

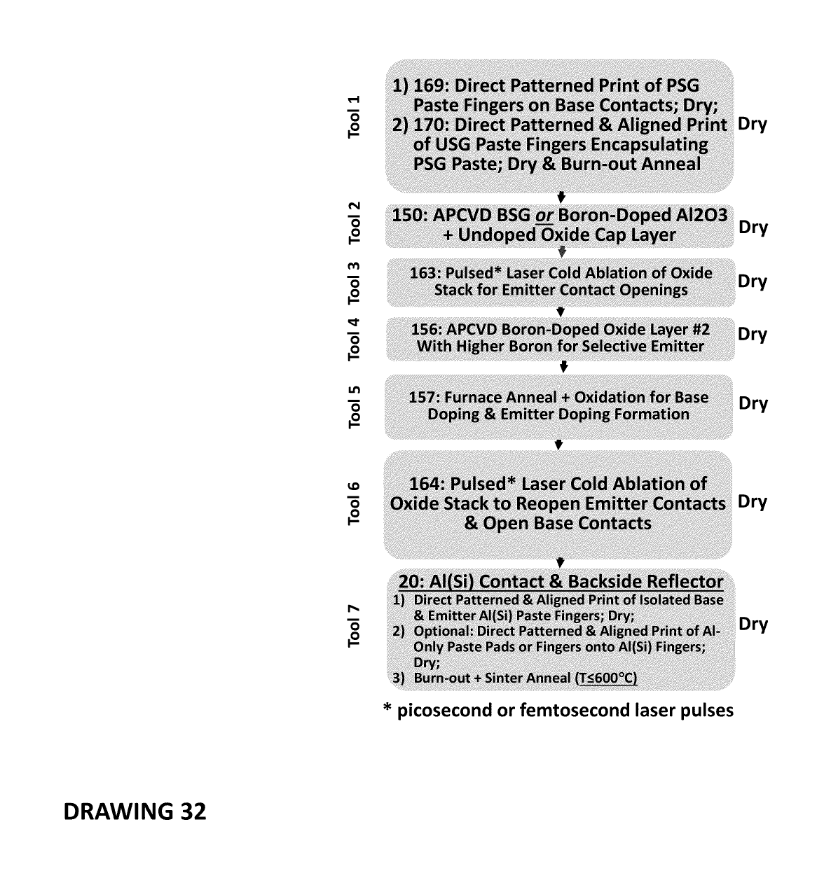

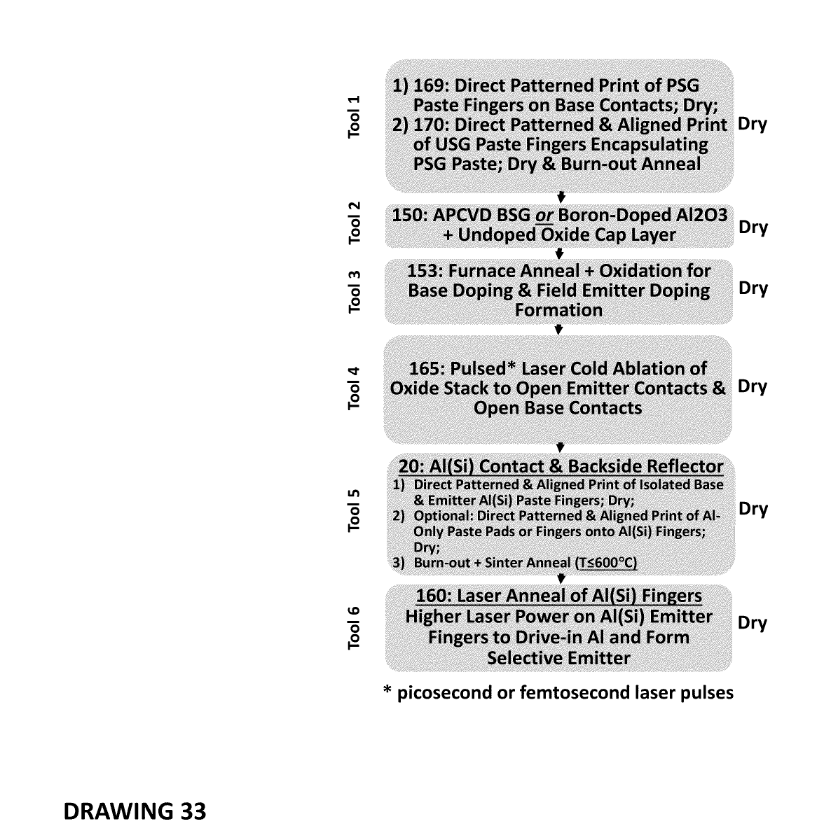

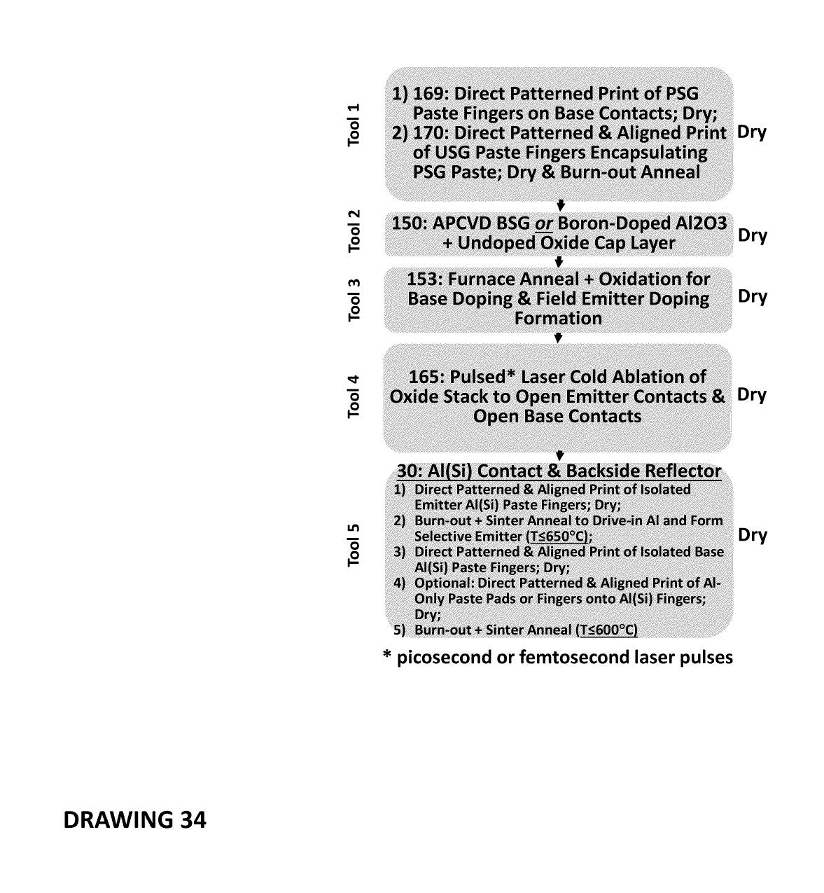

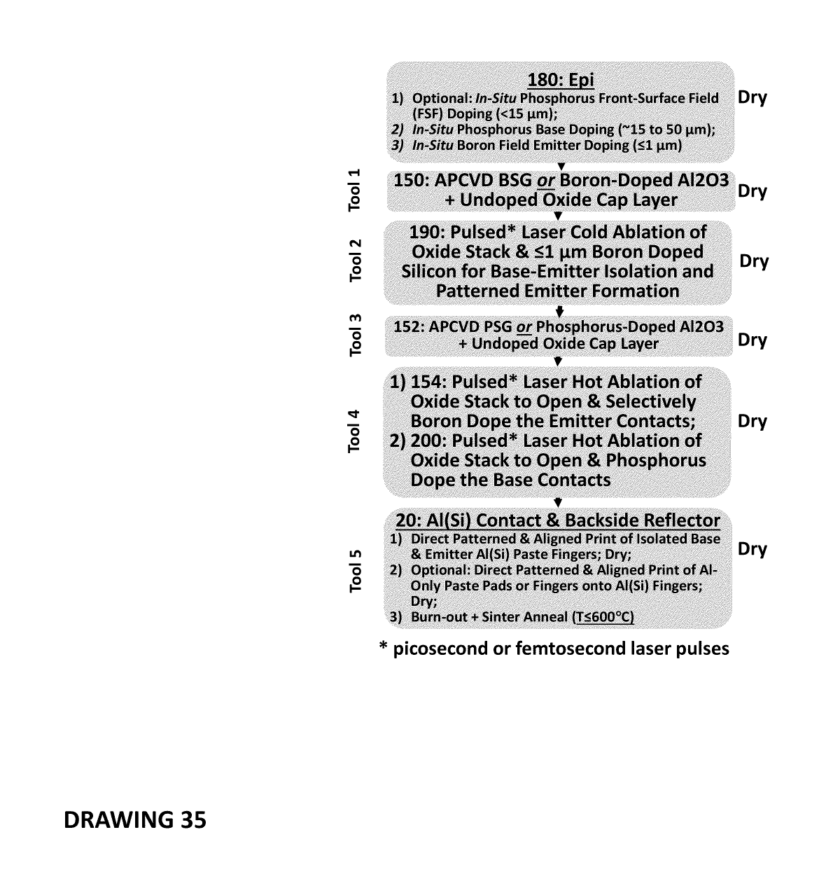

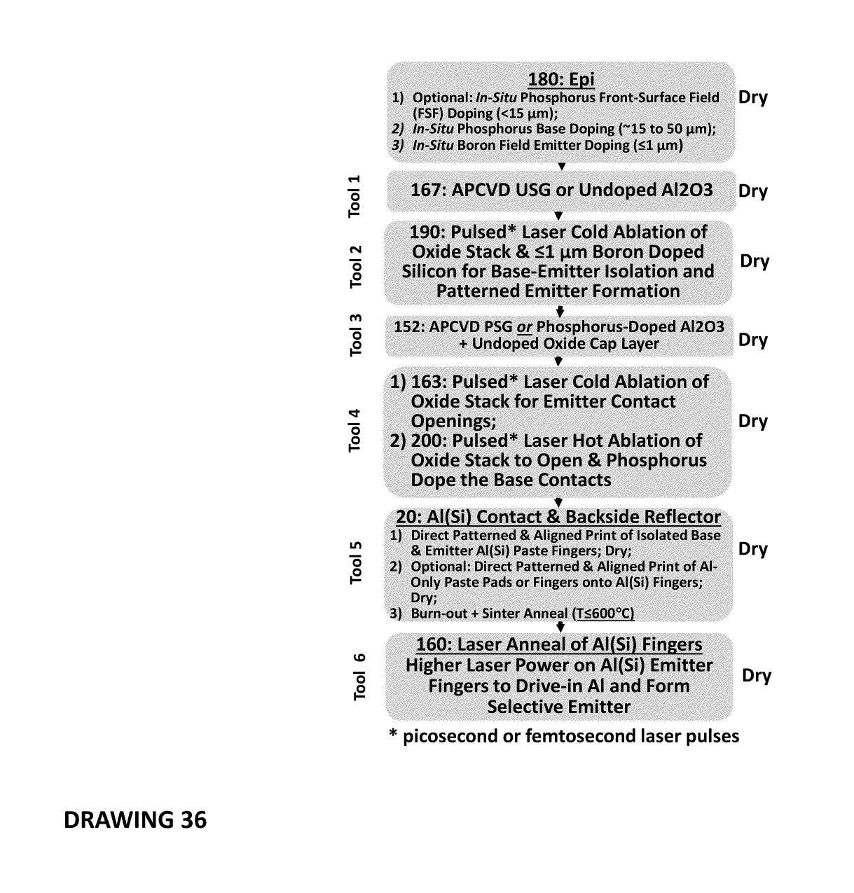

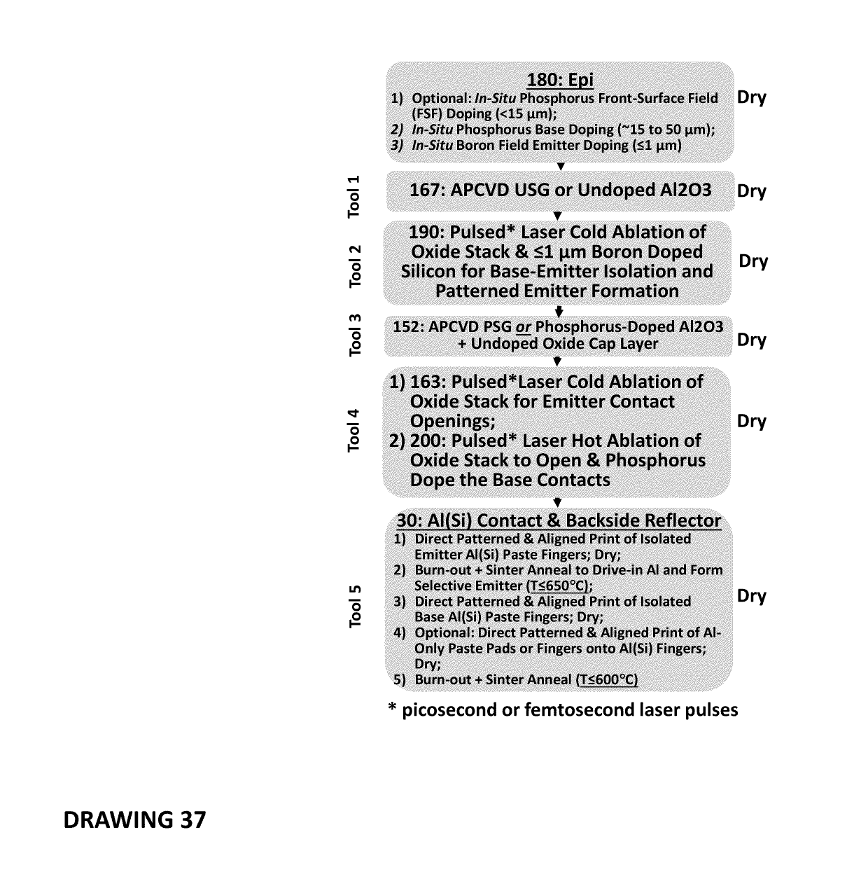

### CROSS-REFERENCE TO RELATED APPLICATIONS

This application claims the benefit of U.S. Provisional Pat. App. Nos. 61/617,023 filed on Mar. 28, 2012 and 61/725,981 filed Nov. 13, 2012, which are hereby incorporated by reference in their entirety.

This application is a continuation-in-part of U.S. patent application Ser. No. 13/204,626 filed on Aug. 5, 2011, Ser. No. 13/807,631 filed Dec. 28, 2012, and Ser. No. 13/731,112 filed Dec. 31, 2012, which are hereby incorporated by reference in their entirety.

### FIELD OF THE INVENTION

The present disclosure relates in general to the fields of solar photovoltaic (PV) cells, and more particularly to back contact solar cells.

### BACKGROUND

Lower manufacturing costs in conjunction with higher conversion efficiencies are key requirements to accelerate the global proliferation of solar photovoltaic (PV) systems as a renewable energy solution and alternative to carbon based fuels. Equally important is increasing solar cell energy yields for a high energy harvest from the PV modules. Standard crystalline silicon solar cell technology for many years has used 150 to 200 micrometers thick silicon substrates, which often acts as the dominating cost and primary contributor to the relatively high cost of the silicon solar PV cells and modules. The cost of standard silicon wafers formed by wire saw from ingots or cast bricks is relatively high because of the costly and energy-intensive multiple processing steps (such as polysilicon, ingot, wire saw wafering) required for fabrication of such wafers.

The second most expensive material in many current standard front contact crystalline silicon solar cell technology is silver metal—particularly expensive as it is a precious metal. A silver paste is often used to contact a frontside n-type emitter of a p-type base solar cell.

Further, for higher efficiency interdigitated back-contact/back-junction (IBC) crystalline solar cells, metallization processing often uses relatively expensive vacuum deposition and lithography/screen print wet-etch patterning as well as electro-chemical plating (for relatively thick, about 30 to 60 microns of copper plating deposition) processing. The manufacturing process tools needed for such metallization processing sequence (including vacuum processing: physical-vapor deposition, patterning, etching, and plating) have a high capital cost, and the chemical plating/patterning processes use sacrificial consumables (such as resist patterning) and result in a large output of hazardous waste (for instance, during copper plating). In addition, the relatively large amount of copper used in thick copper metallization in an IBC cell may further contribute to the overall cell and module manufacturing costs. Thus, lower cost metallization materials and processes are needed to enable low cost solar cells.

### BRIEF SUMMARY OF THE INVENTION

Therefore, a need has arisen for improved back contact solar cell structures and fabrication methods. In accordance with the disclosed subject matter, methods and structures for photovoltaic back contact solar cells having aluminum-silicon alloy layer metallization are disclosed which substantially eliminate or reduce the cost and fabrication disadvantages associated with previously developed back contact solar cell structures and fabrication methods.

According to one aspect of the disclosed subject matter, methods for forming an interdigitated back-contact solar cell structure on a crystalline semiconductor absorber layer are provided. In one embodiment, a passivation and antireflection coating layer is formed on the frontside of a semiconductor absorber and a thicker lightly doped n-type base layer and a thinner heavily doped p-type emitter junction are formed on the backside of the semiconductor absorber. A backside structure is formed on the thicker lightly doped n-type base layer and the thinner heavily doped p-type emitter junction on the backside of the semiconductor absorber by the following: forming a patterned backside dielectric dopant source and passivation structure with base and emitter contact openings; forming a first interdigitated base and emitter metallization layer comprising a plurality of direct-write printed silicon-containing aluminum fingers directly on the patterned backside dielectric dopant source and passivation structure and contacting the base and emitter regions through the base and emitter contact openings; forming an electrically insulating backplane layer comprising a plurality of via holes landing on the first interdigitated base and emitter metallization layer, the backplane layer attached to the patterned backside dielectric dopant source and passivation structure and the first patterned interdigitated base and emitter metallization layer; and, forming a second interdigitated base and emitter metallization layer comprising patterned conductor fingers aligned substantially orthogonal to the first interdigitated base and emitter metallization layer on the electrically insulating backplane layer.

According to another aspect of the disclosed subject matter, methods for forming an interdigitated back-contact solar cell structure on a crystalline semiconductor absorber layer are provided. In one embodiment, a back contact solar cell comprising a multi-level metallization structure is provided. The multi-level metallization structure has a first aluminum-silicon alloy layer positioned on the backside surface of a semiconductor solar cell substrate, the aluminum-silicon alloy layer comprises base electrodes and emitter electrodes connected to the base regions and emitter regions on the solar cell substrate. An electrically insulating backplane layer is positioned on the first aluminum-silicon alloy, the backplane layer comprises via holes to access said first aluminum silicon alloy layer which are drilled through the backplane layer and stopped at the first aluminum-silicon alloy layer at selective positions to form base contacts and emitter contacts to the first metal layer without punching through the first aluminum-silicon alloy layer. A second layer of electrically conductive metal is positioned on the electrically insulating backplane layer and electrically contacts to the first aluminum silicon alloy layer through the via holes.

And according to yet another aspect of the disclosed subject matter, a silicon-containing aluminum alloy comprising aluminum-silicon alloy particles shaped substantially as a mixture of flake-shaped particles and spherical-shaped particles for forming an interdigitated back-contact base and emitter contact metallization structure are provided.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

Drawing 1 is a cross section of an IBC thin silicon solar cell with a dielectric backplane support, and with Al(Si) Paste;

Drawing 2 is a cross section of an IBC thin silicon solar cell with a dielectric backplane support, and with Al-only paste on Al(Si) Paste;

Drawing 3 is top view of Al-only paste pads printed on Al(Si) paste emitter and base isolated fingers;

Drawing 4 is top view of backplane metal emitter and base isolated fingers on the dielectric backplane;

Drawings 5A and 5B are diagrams showing backside views a metal 1 layer (M1) and a dielectric backplane layer with vias, respectively;

Drawing 6 is diagram showing backside view of a metal 2 layer (M2);

Drawing 7 has two process flow diagrams options for Al(Si) paste print and anneal;

Drawing 8 is a Process Flow Diagram for Manufacturing Thin Silicon Solar Cells By Laser Splitting and Liftoff Release of Thin Silicon Layer from a reusable silicon support wafer;

Drawing 9 is a Process Flow Diagram for Manufacturing Thin Silicon Solar Cells By Laser Splitting and Liftoff Release of a thin Epitaxial Silicon Layer from a reusable silicon support wafer;

Drawing 10 is a Process Flow Diagram for Manufacturing Thin Silicon Solar Cell By Laser Splitting and Liftoff Release of Epitaxial Silicon Layer From Porous Silicon Layer;

Drawing 11 is a Process Flow Diagram for Manufacturing Thin Silicon Solar Cells By Mechanical Liftoff Release of a thin Epitaxial Silicon Layer from a sacrificial porous silicon bilayer on a reusable silicon support wafer;

Drawing 12 is a Process Flow Diagram for Manufacturing Thin Silicon Solar Cells By Frontside Silicon Etch and Texture of a silicon wafer;

Drawing 13 has process flow options for Backplane Metallization;

Drawing 14 is a Table Summary of Cell Backside Process Flow Options for Selective Emitter and for each process flow option, a count is shown for the total number of APCVD tools, number of laser tools for oxide ablation, and number of prints on cell backside;

Drawing 15 is a process flow diagram for Cell Backside Process Flow Option 130A. Ex-Situ Emitter with APCVD Boron Oxide and Abutted Junction;

Drawing 16 is a process flow diagram for Cell Backside Process Flow Option 130B. Ex-Situ Emitter with APCVD Boron Oxide and Abutted Junction;

Drawing 17 is a process flow diagram for Cell Backside Process Flow Option 130C. Ex-Situ Emitter with APCVD Boron Oxide and Abutted Junction;

Drawing 18 is a process flow diagram for Cell Backside Process Flow Option 130D. Ex-Situ Emitter with APCVD Boron Oxide and Abutted Junction;

Drawing 19 is a process flow diagram for Cell Backside Process Flow Option 130E. Ex-Situ Emitter with APCVD Boron Oxide and Abutted Junction;

Drawing 20 is a process flow diagram for Cell Backside Process Flow Option 130F. Ex-Situ Emitter with APCVD Boron Oxide and Abutted Junction;

Drawing 21 is a process flow diagram for Cell Backside Process Flow Option 130G. Ex-Situ Emitter with APCVD Boron Oxide and Abutted Junction;

Drawing 22 is a process flow diagram for Cell Backside Process Flow Option 130H. Ex-Situ Emitter with APCVD Boron Oxide and Abutted Junction;

Drawing 23 is a process flow diagram for Cell Backside Process Flow Option 131A. Ex-Situ Emitter with APCVD Boron Oxide and Isolated Junction by APCVD Undoped Oxide;

Drawing 24 is a process flow diagram for Cell Backside Process Flow Option 131B. Ex-Situ Emitter with APCVD Boron Oxide and Isolated Junction by APCVD Undoped Oxide;

Drawing 25 is a process flow diagram for Cell Backside Process Flow Option 131C. Ex-Situ Emitter with APCVD Boron Oxide and Isolated Junction by APCVD Undoped Oxide;

Drawing 26 is a process flow diagram for Cell Backside Process Flow Option 131D. Ex-Situ Emitter with APCVD Boron Oxide and Isolated Junction by APCVD Undoped Oxide;

Drawing 27 is a process flow diagram for Cell Backside Process Flow Option 132A. Ex-Situ Emitter with APCVD Boron Oxide and Isolated Junction by Printed USG;

Drawing 28 is a process flow diagram for Cell Backside Process Flow Option 132B. Ex-Situ Emitter with APCVD Boron Oxide and Isolated Junction by Printed USG;

Drawing 29 is a process flow diagram for Cell Backside Process Flow Option 132C. Ex-Situ Emitter with APCVD Boron Oxide and Isolated Junction by Printed USG;

Drawing 30 is a process flow diagram for Cell Backside Process Flow Option 132D. Ex-Situ Emitter with APCVD Boron Oxide and Isolated Junction by Printed USG;

Drawing 31 is a process flow diagram for Cell Backside Process Flow Option 132E. Ex-Situ Emitter with APCVD Boron Oxide and Isolated Junction by Printed USG;

Drawing 32 is a process flow diagram for Cell Backside Process Flow Option 132F. Ex-Situ Emitter with APCVD Boron Oxide and Isolated Junction by Printed USG;

Drawing 33 is a process flow diagram for Cell Backside Process Flow Option 132G. Ex-Situ Emitter with APCVD Boron Oxide and Isolated Junction by Printed USG;

Drawing 34 is a process flow diagram for Cell Backside Process Flow Option 132H. Ex-Situ Emitter with APCVD Boron Oxide and Isolated Junction by Printed USG;

Drawing 35 is a process flow diagram for Cell Backside Process Flow Option 133A. In-Situ Emitter with Boron-Doped Epi and Isolated Junction by Laser Si Ablation;

Drawing 36 is a process flow diagram for Cell Backside Process Flow Option 133B. In-Situ Emitter with Boron-Doped Epi and Isolated Junction by Laser Si Ablation; and

Drawing 37 is a process flow diagram for Cell Backside Process Flow Option 133C. In-Situ Emitter with Boron-Doped Epi and Isolated Junction by Laser Si Ablation.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

Importantly, the exemplary process flows, materials, and dimensions disclosed in relation to specific embodiments are provided both as detailed descriptions for specific embodiments and to be used generally when forming and designing solar cells in accordance with the disclosed subject matter. One having skill in the art will recognize that aspects of the described process flows and structures may be combined and/or added or deleted in numerous and various ways to form solar cells in accordance with the disclosed subject matter.

And although the present disclosure is described with reference to specific embodiments, such as back contact solar cells using monocrystalline silicon substrates having a thickness in the range of 10 to 200 microns and other described fabrication materials metallization layers, one skilled in the art could apply the principles discussed herein other fabrication materials including alternative semiconductor materials (such as gallium arsenide, germanium, multi-crystalline silicon, etc.), metallization layers comprising metallization stacks, technical areas, and/or embodiments without undue experimentation.

Often, aluminum pastes that are used for industry standard front contact solar cell designs cannot be directly integrated to make high efficiency IBC solar cells. Typical industry standard aluminum pastes are designed to fire, i.e. anneal, at high temperature with short time to create a deep diffusion of aluminum into silicon. For standard solar cells with a p-type crystalline silicon absorber the deep diffused aluminum may provide a desired back surface field. For n-type IBC solar cells the standard aluminum paste and fire anneal results in degradation of cell efficiency or severe electrical shunting.

The following disclosure provides solutions and processes for making high efficiency n-type IBC solar cells with an aluminum based paste/ink. An aluminum alloy paste/ink with a silicon composition in conjunction with anneal process options and cell integration process flow options are disclosed to minimize the diffusion and spiking into silicon and enable a high solar cell efficiency.

Further, manufacturing methods that combine thin crystalline silicon substrates with simpler processing and aluminum-based metallization may significantly reduce the cost of crystalline silicon solar cells. And as the most common metal in the earth's crust, aluminum is a relatively cheaper metal compared to silver or copper. The high-efficiency cell architectures and process flows provided, such as the back-contact IBC structures detailed herein, formed in conjunction with simpler and lower cost methods may reduce processing costs (and in some instances silicon thickness) in the solar cell fabrication process and provide significant cost reduction and performance enhancements of crystalline silicon solar cells and modules.

The present application discloses and describes various structures and manufacturing methods for high-efficiency thin-silicon solar cells using for example a screen-printable aluminum-based alloy paste—and more specifically an aluminum-silicon Al(Si) alloy paste—to form contact metallization on both the emitter and base contacts and interdigitated back-contact (IBC) of a high efficiency solar cell. Specific examples are provided for monocrystalline silicon solar cell with an n-type base absorber and a p-type backside emitter junction. Processes are described for formation of selective emitter comprising an emitter junction region (covering most of the emitter area) with lighter p-type in conjunction with more heavily doped p-type doped regions (covering a relatively small fraction of the emitter area) under the emitter contacts in order to achieve higher cell efficiency. All processes as described herein are compatible with manufacturing a crystalline silicon absorber having a thickness as thin as about 1 micrometer and as thick as up to about 100 micrometers and which is supported throughout manufacturing by a reusable silicon support wafer and/or a laminated dielectric support backplane structure (for example a flexible backplane). The final solar cell silicon absorber layer may be directly split from the silicon support wafer by laser processing. Alternatively, the thin silicon absorber may be an epitaxial layer deposited onto and subsequently mechanically released from a sacrificial porous silicon layer formed on the silicon support wafer and separated using a mechanical release/lift-off process. Alternatively, the structures, materials, and processes disclosed herein may be used on solar cells fabricated using crystalline wafers formed by wire saw from monocrystalline ingots or cast quasi-mono bricks. Further, in addition to a first level aluminum-alloy-based printed paste metallization (Metal 1 or M1) formed directly on the solar cell (on-cell), low cost process options for the second layer monolithic metallization (Metal 2 or M2) on an electrically insulating support backplane, such as a dielectric layer, are also provided.

And while the exemplary manufacturing methods and structures described in this invention are for fabricating high-efficiency monocrystalline silicon solar cells with silicon absorber thickness in the range of about 1 micron up to about 100 micrometers (microns), aspects and methods disclosed herein may also be used for solar cells using thicker absorbers based on starting silicon wafers made from CZ ingots or cast bricks. In many instances, the solar cells described have an n-type base with a p-type emitter formed on the backside of the cell (for an IBC cell design). Electrical contacts to both emitter and base are made on the backside of the cell (opposite the sunnyside), thus the frontside does not have electrical contacts and is free of optical shading. The thin silicon cell may be supported at all times during the manufacturing process by either a thick reusable silicon support wafer on or from which it is formed and/or a laminated dielectric backplane. For process flow options using the reusable silicon support wafer, solar cell backside processing may be completed prior to release of the thin silicon absorber layer from the silicon support wafer. Importantly, the methods and structures disclosed herein may also be applied to solar cells made using standard starting silicon wafers (and without the use of any reusable templates).

Process flow alternatives and variations for fabricating and patterning the emitter junction as well as the passivation and IBC metallization layers on the backside of the solar cell are also provided. The described process flow variations use printable aluminum-based metallization, for example an aluminum-silicon Al(Si) alloy paste, to make electrical contacts to both the n-type base and p-type emitter, and to form the on-cell IBC metallization fingers. The described process flow embodiments result in a selective lighter doped emitter over a relatively larger fraction of the emitter region in conjunction with more heavily doped p-type doped silicon regions under the emitter contacts (covering a relatively smaller fraction of the emitter region) in order to achieve higher cell efficiency.

Process flow variations are described for making both abutted junctions or isolated junctions on the backside of the cell. An abutted junction has an abrupt gradient in doping occurring across a small space region between the p-type emitter and heavily doped n-type contacts. An isolated junction has a low doped lateral gap region, typically with a distance of less than 100 micrometers, separating the p-type emitter and the heavily doped n-type contacts. Process flow embodiments for cell with an abutted junction may often be simpler (by at least one process step) as compared to process flow variations for cell with an isolated junction; however, cell efficiency may be compromised by higher recombination velocity of minority carriers in an abrupt abutted junction.

The described manufacturing process flows start with a clean monocrystalline silicon support wafer. The wafer is wet cleaned using for example dilute potassium hydroxide (KOH) and a dilute mixture of hydrochloric acid (HCl) and hydrofluoric acid (HF). The silicon support wafer may have starting thickness (for example a thickness of at least approximately 150 to 200 microns for 156 mm×156 mm solar cells) that enables reliable mechanical handling with minimal or negligible breakage.

A thin silicon absorber layer (for example having a thickness less than approximately 100 micrometers, and more specifically in the range of approximately 25 to 75 microns or thinner) may be directly split and released from the silicon support wafer by use of scanning focused lasers that permeate through the silicon support wafer (or alternatively may be formed by etching back a thicker starting wafer to the final desired absorber thickness).

At least some portion (or all) of the final silicon absorber layer may contain an epitaxially deposited silicon layer. If the epitaxial silicon layer is deposited on a silicon support wafer with a sacrificial porous silicon bilayer, then the relatively thin (e.g., in the range of about 20 to 80 microns in thickness) epitaxial silicon layer may be mechanically lifted and released from the silicon support wafer after completion of a portion of cell processing through the attachment of a backplane sheet. A bilayer of porous silicon may be formed by a wet anodic etch process on one side of the silicon support wafer (also called template). The porous silicon bilayer may comprise a lower porosity (e.g., porosity of less than about 40%) porous silicon layer of thickness less than five micrometers on top of a higher porosity (e.g., porosity of greater than about 50%) porous silicon layer of thickness less than five micrometers. For instance, the total porous silicon bilayer thickness may be in the range of less than 1 micron up to about 5 microns. An atmospheric pressure chemical vapor deposition (APCVD) epitaxial process is used to deposit the epitaxial silicon layer, for example with a thickness of less than about 80 micrometers. An APCVD epitaxial silicon tool is often a low cost hardware choice as compared to vacuum based deposition tools. Trichlorosilane (TCS) may be used as the silicon precursor. If the silicon support wafer has a porous silicon bilayer, then during initial hydrogen prebake process and the subsequent epitaxial deposition process, the porous silicon bilayer structure evolves and transforms to make it an excellent epitaxial seed and release layer. A portion of the porous silicon bilayer (the lower porosity portion) is transformed to a quasi monocrystalline silicon (QMS) layer on top of the higher porosity release layer. During the initial in-situ hydrogen pre-bake process (for example performed at a wafer temperature of about 1000° C. to 1150° C.), the pores on the porous silicon surface close (as the QMS layer is formed) and the porous silicon surface serves as an excellent seed for epitaxial silicon deposition, conforming to the monocrystalline structure of the underlying template wafer through the porous silicon bilayer. The porous silicon bilayer serves as a barrier and suppresses the diffusion of dopants and impurities from the silicon support wafer into the epitaxial silicon layer. The porous silicon bilayer also serves as a gettering sink to trap metallic impurities, enabling high-efficiency cell fabrication. An n-type front surface field (FSF) layer with thickness less than 15 micrometers and in-situ phosphorus doping concentration of about 1×10¹⁷ cm⁻³ to 1×10¹⁹ cm⁻³ may be first epitaxially deposited by, for example, mixing phosphine gas (PH3) with TCS during epitaxial silicon deposition at a process in the temperature range from about 1050° C. to 1150° C. The n-type epitaxial base layer is then grown with an in-situ phosphorus doping concentration in range from about 8×10¹⁴ cm⁻³ to about 3×10¹⁶ cm⁻³ to increase the total epitaxial layer thickness to a total thickness in the desired range of about 30 to 80 micrometers.

A p-type emitter in the large field area on the backside of the cell may be formed in situ during epitaxial silicon deposition, or formed ex situ by drive-in diffusion from a deposited doped oxide thin film. For in-situ epitaxial formation of the emitter, the epitaxial deposition process is done by switching from phosphine gas to a p-type dopant gas such as diborane (B2H6) to form a p-type emitter, for example having a thickness less than one micrometer. A peak boron surface concentration in the in-situ field emitter may be in the range of about 1×10¹⁸ cm⁻³ to 1×10¹⁹ cm⁻³ for selective emitter while higher doping concentrations may be used without selective emitter.

Ex-situ doping to form an emitter may be achieved by diffusion of boron from a boron-doped oxide thin film, for example having a thickness in the range of 20 to 100 nanometers, that is deposited by APCVD (for example using silane and oxygen). The APCVD oxide thin film may be a borosilicate glass (BSG) or a boron-doped aluminum oxide (Al2O3). Typical boron content is about 0.5% to 5% in the APCVD boron-doped oxide film. A thin undoped oxide layer of thickness less than 50 nanometers also may be deposited on top of the doped oxide to encapsulate the hygroscopic surface of the doped oxide. The thickness of the APCVD oxide along with the thickness of overlying subsequent APCVD oxide films may be optimized for maximum backside optical (IR) reflectance while meeting the solid source doping and backside passivation requirements. The diffusion or drive-in of boron may be performed in a furnace with a high temperature thermal anneal and oxidation process. The furnace anneal temperature and time is set to optimize the diffusion and doping of the field emitter. A temperature and time for the furnace anneal process is in the range of about 900° C. to 1150° C. for 10 to 90 minutes in nitrogen (N2) ambient followed by an optional 5 to 15 minutes in oxygen (O2) ambient. A peak boron surface concentration in the ex-situ field emitter is in the range of 1×10¹⁸ cm⁻³ to 1×10¹⁹ cm⁻³ after drive-in diffusion for selective emitter while higher doping concentrations may be used without selective emitter.

The APCVD oxide thin film may also function as a cell backside passivation layer on the emitter. Regarding passivation, aluminum oxide (Al2O3 or non-stoichiometric AlOx) with a natural internal negative fixed charge may enable enhanced field-effect passivation of the underlying p-type emitter where electrons are the minority current carriers. The high-temperature anneal and short thermal oxidation densifies the APCVD film and oxidizes the interfaces to further improve passivation.

Patterned emitter formation may be performed by pulsed (for example picoseconds or femtoseconds) laser ablation of the APCVD boron-doped oxide film to pattern the oxide layer prior to diffusion anneal (for cells with ex-situ emitter) or by pulsed laser ablation of the epitaxially grown boron-doped in-situ emitter (when emitter is formed in situ during silicon Epitaxy). The pulsed laser tool may have capability for picosecond or femtosecond laser pulsing in order to minimize the Heat-Affected Zone (HAZ). A “cold” pulsed picoseconds or femtoseconds laser ablation process prevents diffusion of dopants into silicon and minimizes formation of the HAZ during the laser ablation process. The laser ablation processes enable fewer cell fabrication process steps and eliminate the use of most consumables compared to more expensive lithographic and wet etch patterning processes.

Doping of n-type base contacts on the backside of the cell may be performed by diffusion of phosphorus from a doped oxide, for example deposited by APCVD or printed. For APCVD, the deposited film, for example having a thickness in the approximate range of 20 to 100 nanometers, may be phosphor silicate glass (PSG: which is silicon dioxide doped with phosphorus) or phosphorus-doped Al2O3 (or AlOx). A phosphorus content may be in the approximate range of 3% to 7% in the phosphorus-doped oxide. A thin undoped oxide (silicon dioxide and/or aluminum oxide) cap layer of thickness less than 50 nanometers also may be deposited on top of the APCVD doped oxide to encapsulate the hygroscopic surface of the APCVD doped oxide. A peak surface phosphorus concentration may be greater than about 3×10¹⁹ cm⁻³ (for example at least 1×10²⁰ cm⁻³) in the base contacts after drive-in diffusion. For printing-based processing, available pastes (or inks) are for example doped PSG silicate pastes (or inks). Optional tools for direct pattern printing include screen print, inkjet print, aerosol jet print, or laser transfer print. If a PSG paste is directly pattern printed as an alternative to APCVD, then a laser pattern processing step may be eliminated to potentially reduce cost of the manufacturing process flow.

Isolation of the base and emitter junctions for a cell with an ex-situ emitter may be performed by patterned alignment, prior to the batch furnace anneal, of an undoped oxide layer onto the silicon area around the phosphorus-doped oxide that is in contact with silicon. The APCVD undoped oxide serves as a diffusion barrier and blocks the diffusion of dopant into the silicon to retain a lightly-doped space region or lateral gap between base diffusion and emitter junction. The undoped oxide layer may be an APCVD undoped silicate glass (USG) or APCVD undoped Al2O3 (or AlOx), or a combination thereof. The undoped oxide also may be a printed USG silicate paste (or ink). Optional tools for direct pattern printing include screen print, inkjet print, aerosol jet print, or laser transfer print. If USG paste is directly pattern printed as an alternative to APCVD undoped oxide, then a laser pattern processing step may be eliminated to potentially achieve lower manufacturing cost.

For a cell using an in-situ emitter, a high temperature furnace anneal may not be used in order to prevent redistribution and diffusion of the epitaxial boron emitter. Rather for a cell with in-situ emitter, a hot laser ablation process (for example using a pulsed nanoseconds laser tool) may be used during the contact opening to simultaneously ablate the doped oxide and drive-in dopant (e.g., phosphorus from PSG) into base contact regions. Isolation of the base and emitter junctions for a cell using an in-situ emitter may be achieved by oversizing the openings during the cold pulsed laser ablation of the boron-doped silicon, and then making smaller recessed base contact openings in the overlying phosphorus-doped oxide during hot laser ablation.

Use of selective emitter (emitter with lighter boron doping) in conjunction with higher doping of the emitter contacts compared to the doping of the main emitter area may lower contact resistance to the emitter, improve the emitter passivation, and increase the solar cell efficiency. Four exemplary methods are provided for implementing the selective emitter. One method involves hot laser ablation (for instance, using pulsed nanoseconds laser processing) of the boron-doped oxide (APCVD BSG) during contact opening. Boron from BSG is driven into the emitter contacts simultaneously during the hot ablation of the boron-doped oxide (BSG).

A second processing method with an ex-situ emitter involves depositing a second APCVD boron-doped oxide (APCVD BSG) layer with a relatively high boron content up to about 6 to 10% and thickness in the approximate range of 20 to 100 nanometers onto the cell backside, with this second BSG layer selectively coming in contact with underlying silicon through the patterned openings in the underlying first APCVD boron-doped oxide layer, and then utilizing the high temperature furnace anneal to simultaneously drive in the boron into silicon to form the main less heavily doped field emitter (covering most of the emitter area) and the more heavily doped emitter contacts (covering a smaller fraction of the emitter area). A thin undoped oxide layer of thickness less than about 50 nanometers may be deposited on top of the doped oxide to encapsulate the hygroscopic surface of the doped oxide. In this scheme, the higher boron content in the second APCVD boron-doped oxide (BSG) layer is optimized to achieve higher doping concentration on the emitter contacts with peak surface boron concentration greater than 3×10¹⁹ cm⁻³ (for example at least 1×10²⁰ cm⁻³).

After the oxide layers on the cell backside are deposited, patterned, or printed, and after furnace drive-in diffusion of the dopants (both boron and phosphorus) according to a pre-designed emitter and base pattern, and after the final laser ablation process of the oxide layers for contact openings to the emitter and base regions, then an aluminum-based paste, for example an Al(Si) alloy (mostly comprising aluminum with a relatively small silicon content, for example between approximately 1% and 20% silicon content by weight, and in some instances less than 12% silicon content) paste finger lines are directly aligned and printed onto the emitter and base contact openings. Thickness of printed Al(Si) finger lines may be less than about 30 micrometers (for example in the range of approximately 1 micrometer or micron up to about 15 micrometers). Optional direct write printing tools include screen print, inkjet print, aerosol jet print, or laser transfer print. An Al(Si) paste for high efficiency IBC cells may have high-purity aluminum particles with silicon content (either embedded and alloyed within aluminum particles as Al—Si alloy particles or mixed with aluminum particles as silicon particles) from 1% to 20% (for example in the range of approximately 1% to 3%) to minimize spiking into the silicon absorber layer and intermixing of aluminum with the silicon in the underlying silicon contacts during the post-printing thermal anneal processing.

An aluminum only (Al-only) paste without silicon also may be directly aligned and printed onto the Al(Si) paste (with the Al only paste not contacting the silicon contacts directly). The Al-only paste print pattern may be finger lines that match the underlying Al(Si) finger pattern, or may be pads which are aligned to the laser drilled holes in backplane. The Al-only paste may help stop laser drilling of holes in backplane, reduce line resistance, and reduce contact resistance to the backplane metallization. Thickness of Al-only finger lines or pads in the above configuration may be selected to be less than about 25 micrometers.

After printing, the Al(Si) paste and Al-only paste may be thermally annealed to dry or evaporate the solvent, burn-out the binder, and sinter for low line resistance.

Third and fourth methods for forming selective emitter (with lighter boron doping for the main emitter regions which account for a much larger fraction of the emitter area and heavier boron doping for the emitter contact regions which account for a smaller fraction of the emitter area) involve thermal eutectic mixing of aluminum from the printed Al(Si) paste. Aluminum is a p-type dopant in silicon and may be used to make the heavily doped emitter contact regions as part of a selective emitter structure and process.

A third method for forming the heavily doped contacts in a selective emitter structure uses a pulsed laser beam, for example a pulsed nanoseconds laser beam, to selectively heat the Al(Si) paste on the emitter contacts (patterned anneal) to a higher temperature (above the eutectic melt temperature of aluminum-silicon) compared to the Al(Si) paste on the base. The higher temperature on the Al(Si) above the emitter contacts (because of the pulsed nanoseconds laser irradiation on these areas) will cause heavy p+ doping by aluminum in the underlying silicon emitter contact areas. For significant aluminum doping in silicon, the temperature at the interface between Al(Si) paste and the underlying silicon needs to be higher than or close to the aluminum-silicon eutectic temperature, which is approximately 577° C.

A fourth method for forming heavily doped emitter contacts in conjunction with less heavily doped selective emitter is by double printing and double annealing of the Al(Si) paste. In this method the Al(Si) paste (or ink) is first printed and annealed on the emitter contact openings (at a higher temperature, for example higher than the eutectic temperature of aluminum-silicon). Then second the Al(Si) is printed on the base contact openings and annealed (at a lower temperature, for example slightly lower than the eutectic temperature of aluminum-silicon). The total thermal budget of the Al(Si) on the emitter contacts with two anneals is higher, and this may result in more and heavier aluminum doping to form the more heavily doped contact regions in conjunction with a selectively doped emitter (with lighter doping for the main emitter regions). The first anneal with Al(Si) on the emitter also may be performed at a higher temperature, for example at a temperature of approximately 577° C. up to 650° C., for heavier aluminum doping of the emitter contacts (to form the p++ heavily doped emitter contacts) compared to the second anneal that is typically less than 600° C. and often lower than the aluminum-silicon eutectic temperature of 577° C.

After printing and annealing of the Al(Si) paste and optional Al-only paste, processing of the cell backside on the silicon absorber layer may be complete. Next, a backplane support sheet (for example having a thickness in the range of approximately 20 to 300 micrometers, such as a prepreg sheet in the range of 50 to 100 micrometers) is aligned, permanently laminated, and cured onto the cell backside. A low cost (and much lower cost as compared to silicon) electrically insulating backplane material with suitable properties (coefficient of thermal expansion, thermal and chemical stability, etc.) is selected for good adhesion onto the backside of the cell, and for reducing mechanical stress in silicon. Backplane materials that are not electrically conductive are selected to prevent electrical shunting of emitter and base metallization, and to allow for a double-level cell metallization structure. Optional backplane materials include composites, pastes, and/or resins of flexible polymers and plastics that have a relatively low in-plane coefficient of thermal expansion (CTE) close to CTE of silicon (for instance backplane sheet material CTE on the order of about 2 to 5 ppm/° C.), and that may be at least somewhat elastic/flexible including some flexibility/elasticity at the interface onto the silicon cell. For post-backplane lamination processing of the thin silicon solar cell, backplane materials are also selected that have chemical resistance and are compatible in wet chemistries for texture and cleaning of silicon, are thermally stable and resistant up to at least 200° C. to 300° C. in a vacuum plasma-enhanced chemical-vapor deposition (PECVD) process, are compatible with laser drilling for making via holes, and finally meet industry-standard solar module reliability and safety requirements.

After lamination and cure of the backplane onto silicon, a suitable laser (such as a pulsed laser source) is used to scribe/cut and define the edge borders of the thin silicon cell. The laser also will define the edge borders of thin silicon cells that are then lifted off and released from the silicon support wafer (in the case of using a reusable wafer/template).

In the case of using a bulk wafer (such as a CZ wafer) for the solar cell itself, there is no lift-off release process and there is no reusable template. The starting wafer itself serves as the solar cell absorber without any reuse.

In the case of a reusable wafer/template process, the release process and tool may be by laser splitting of the thin silicon layer directly from the silicon wafer template. The separation of the thin silicon during lift-off occurs at a plane within the silicon support wafer that was split by a permeable focused scanning laser tool.

Alternatively, in the case of an epitaxial silicon layer on porous silicon bilayer on silicon support wafer (reusable template), the release process may be, for example, by having one vacuum-clamp (or electrostatic clamp) chuck on the silicon support wafer side, and second vacuum-clamp (or electrostatic clamp) chuck on the backplane support of the epitaxial silicon, and then mechanically lifting off the thin silicon from the silicon support wafer. The separation of the laminated solar cell with epitaxial silicon absorber during lift-off release occurs at the higher porosity porous silicon interface with the reusable template.

After separation of the backplane-laminated thin silicon solar cell, the silicon wafer support may be reconditioned/cleaned for next reuse in a series of multiple reuse cycles. Recondition and cleaning processing may include one or a combination of edge grind and polish, surface grind and polish, and/or wet cleaning. After template reconditioning/cleaning, the silicon support wafer (or template) is reused to make another solar cell. Solar cell manufacturing costs may then be further reduced by increasing the number of template reuses of the silicon wafer support (or template).

After lamination and release (in the case of epitaxial silicon solar cell or laser-split solar cell, based on a reusable template), or alternatively after lamination for solar cells made using the same starting wafer as the solar cell absorber and without any release (and without reusable wafer), the frontside of the silicon solar cell is wet etched/textured in an alkaline (e.g., comprising KOH or NaOH) chemistry and cleaned. Industry standard wet chemistry solutions may be used for surface texturing, and cleaning. For example, the wet process sequence of HF dip, deionized wafer (DI) rinse, texture etch in a solution of hot KOH plus a suitable surfactant (such as IPA), and DI rinse, results in etching silicon and forming a random pyramidal textured surface. After wet etch texture, a wet process sequence of rinse, clean in a dilute HF/HCl solution (or an alternate proven surface cleaning chemistry such as the so-called RCA clean), and a final DI rinse and dry, results in a clean surface that is ready for subsequent passivation. In some cases, optimization of the clean, rinse and dry of the textured silicon surface may be critical to achieve good surface passivation.

The textured and cleaned frontside of the cell may then be coated by PECVD thin films that are optimized for surface passivation (resulting in very low surface recombination velocity) and antireflection (AR). The PECVD process temperature may be selected at a sufficiently low temperature to be compatible with the thermal stability of the backplane support material (for instance, at a temperature of ≦300° C.). The first deposition is a thin intrinsic (undoped) amorphous silicon (α-Si:H), amorphous silicon oxide (α-SiOx:H), or amorphous silicon oxycarbide (α-SiOxCy:H) layer (for example having thickness in the range of approximately 1 nm to 5 nanometers) to create a heterojunction interface for enhanced surface passivation (reduced surface recombination velocity) on crystalline silicon. The deposition of this first layer may then be optimized to minimize the interfacial defect state density (Dit). The second deposition is an n-type (phosphorus doped) amorphous silicon (α-Si:H), amorphous silicon oxide (α-SiOx:H), or amorphous silicon oxycarbide (α-SiOxCy:H) (thickness <10 nanometers) with electrical conductivity in the range of about 0.001-0.1 Siemens/cm that is optimized for enhanced front surface passivation quality and stability. This wide bandgap doped second layer enables reduced optical absorption in the blue wavelength (400-600 nanometers) that is a common issue for standard amorphous silicon, α-Si:H. The third and final layer is an amorphous silicon nitride, α-SiNx:H (thickness in the range of 30 to 100 nanometers) with positive fixed charge for enhanced field effect passivation on the underlying n-type crystalline silicon, and is optimized to minimize optical reflectance. Optionally, an optional fourth layer, amorphous silicon oxide, α-SiOx:H (thickness 30 to 100 nanometers) on α-SiNx:H may be used to further reduce the optical reflectance, and to induce an all-black solar cell appearance.

A thermal anneal up to 300° C. may performed after PECVD deposition to further improve passivation. This thermal anneal may be performed in situ in the PECVD tool or subsequently as a follow-on anneal process.

Next a laser tool drills via holes through the backplane for enabling electrical connections to the underlying Al(Si) or Al-only sintered paste. An optimized laser drill process or endpoint detector may be used to stop on or within the Al(Si) or Al-only paste.

The non-conducting backplane is then metalized to interconnect the emitter Al(Si) fingers and separately interconnect the base Al(Si) fingers. For example, one or a combination of the four following backplane metallization process flow options may be used: metal paste, thermal spray, physical vapor deposition (PVD) only, and plating with a PVD seed layer. For backplane metallization options with metal paste and thermal spray, an optional dry or wet etch may be performed before backplane metallization to clean and remove carbon residues and oxides from the via openings.

For backplane metallization with metal paste, an Al(Zn) alloy or Cu(Sn) or solder paste with a flux may be directly printed on the backplane and via openings with a finger pattern that is aligned perpendicular to the underlying Al(Si) fingers. Thickness of metal paste may be at least several micrometers (for example 10's of micrometers) in order to provide sufficient electrical conductivity. Optional tools for direct pattern print of fingers and connecting busbars include stencil print, screen print, inkjet print, aerosol jet print, or laser transfer print. A flux in the metal paste, for example a chlorine based flux, may be used to clean the via holes and remove aluminum oxide from the Al(Si) or Al-only paste at the bottom of the via holes. After print of metal paste, an anneal may be performed to sinter the metal paste. A typical anneal temperature for sintering metal solder pastes is less than 250° C.

For backplane metallization with thermal spray, an atmospheric thermal spray process may be used to directly pattern and align an aluminum and/or copper alloy such as aluminum-zinc (AlZn) alloy fingers on the backplane and via openings. An Al(Zn) alloy may be used to enable easier soldering. By aligning the direction of the Al(Zn) fingers perpendicular to the direction of the underlying Al(Si) fingers—also referred to as an orthogonal pattern—the width of the Al(Zn) fingers may be increased and the number of Al(Zn) fingers may be decreased by a significant factor, for instance, by a factor between about 5× and about 30× (as compared to the on-cell printed paste metallization M1), to make the thermal spray patterning process more manufacturable. Note the laser-drilled via hole pattern in the backplane is designed to align and connect the overlying Al(Zn) finger pattern with the underlying Al(Si) finger pattern. An Al(Zn) busbar for connecting emitter lines and Al(Zn) busbar for connecting base lines also may be directly pattern sprayed onto the backplane for reducing number of soldering points.

For backplane metallization with PVD only process, an optional sputter etch may be first performed to clean the via holes. Then one or a combination of layers of aluminum, nickel vanadium, copper, and tin with thicknesses of several micrometers (total thickness may be as much as ten micrometers) may be deposited by either plasma sputtering or evaporation (or a combination thereof). The PVD layers may then be patterned to form isolated base and emitter fingers and connecting busbars. The metal fingers on the backplane may be pattered perpendicular (orthogonal) to the underlying Al(Si) fingers. Direct patterning may be done by laser ablation of the metal layers. Patterning also may be done by applying a patterned sacrificial mask and wet etching.

For backplane metallization with plating and a PVD seed layer, a sputter etch is first done to clean via holes. Then a plating seed of a suitable metal such as nickel-vanadium (NiV) on aluminum is deposited with thickness of a few micrometers (for example total thickness less than 5 micrometers). Metal patterning to form isolated base and emitter fingers and connecting busbars may be done by laser ablation of the PVD seed. Patterning also may be done by applying a patterned sacrificial resist mask on the PVD seed layer. The metal fingers on the backplane are pattered perpendicular to the underlying Al(Si) fingers (perpendicular to Metal 1 or M1). Before plating, a sacrificial barrier layer may be applied on the cell frontside. Electroplating processes may then be used to plate copper with thickness of several micrometers up to 10's of micrometers (for example less than 100 micrometers) followed by a tin capping layer with thickness of a few micrometers (for example less than 10 micrometers). Electroplating process may be optimized to reduce stress and reduce bowing of the solar cell. After electroplating, sacrificial layers and mask may then be removed by wet etch (unless the seed was patterned using laser ablation prior to the plating process).

If necessary, a final process step in the process flow may be an optional anneal to improve solar cell efficiency (by improving the passivation and/or improving the overall electrically conductivity of the metallization structures). The anneal temperature is lowered to be compatible with the backplane support material. The anneal temperature may be less than 300° C. (for example in the range of about 100° C. to 300° C.), and the cells may be annealed in vacuum or an ambient of air, nitrogen (N2), or forming gas with N2 mixed 3% to 5% percent hydrogen (H2).

The completed IBC thin silicon solar cell is then ready for electrical testing and sorting, and lamination into a solar module using industry standard module building techniques.

Drawing 1 is a cross section of a backplane-laminated IBC thin silicon solar cell with an electrically insulating backplane support (9), and with Al(Si) paste (2) and (3). The n-type silicon absorber base layer (1) may have a thickness less than approximately 80 micrometers (or in some instances may be as thick as approximately 150 micrometers if the backplane-laminated cell is fabricated using a starting wafer without reuse and without any lift-off release) and is phosphorus doped with concentration from about 8×10¹⁴ cm⁻³ to about 3×10¹⁶ cm⁻³. The p-type field emitter (5) has a depth less than 1 micrometer and is boron doped with peak concentration from about 1×10¹⁸ cm⁻³ to 1×10¹⁹ cm⁻³ (for selective emitter; higher doping concentrations may be used without selective emitter). The boron doped oxide (7) is a dopant source for drive-in diffusion of boron into the p-type field emitter (5). The heavily doped p-type contact area (4) for selective emitter structure, for example having a depth of less than approximately 3 micrometers, doped with boron or aluminum peak concentration greater than 3×10¹⁹ cm⁻³ (and in some instances greater than 1×10²⁰ cm⁻³). The heavily doped n-type base contact area (6) has a depth about less than 3 micrometers and is doped with phosphorus peak concentration greater than 3×10¹⁹ cm⁻³ (and for example greater than 1×10²⁰ cm⁻³). The phosphorus doped oxide (8) is a dopant source for drive-in diffusion of phosphorus to make the heavily doped n-type base contact area (6). Several methods for fabricating the selective field emitter area (5), heavily-doped emitter contact area (4) for selective emitter, and the base contact area (6) are described in Drawing 14. Al(Si) paste (2) is in contact with heavily-doped emitter contact area (4), and Al(Si) paste (3) is in contact with the n-type base contact area (6). The electrically insulating backplane (9) may have a thickness in the range of approximately 20 to 300 micrometers (for example 50 to 100 micrometers) and may also serve as a mechanical support for the thin silicon absorber (1). The emitter metal (15) consists of a backplane metal (10), which is part of the second-level metal known as Metal 2, that is connected to Al(Si) paste (2) through via holes in the backplane (9). The base metal (16) consists of a backplane metal (11), which is part of the second-level metal known as Metal 2, that is connected to Al(Si) paste (3) through via holes in the backplane (9). The emitter metal (15) and base metal (16) are electrically isolated. Several methods for fabricating the backplane metal layers (10) and (11) are described in Drawing 13. The frontside (12) of the silicon absorber (1) has a textured surface and is passivated with intrinsic α-Si:H or α-SiOx:H or α-SiOxCy:H and n-type α-Si:H or α-SiOx:H or α-SiOxCy:H, and has an overlying single-layer antireflective coating of α-SiN:H or a dual-layer antireflective coating of α-SiN:H and α-SiO:H.

Drawing 2 is a cross section of a backplane-laminated IBC thin silicon solar cell with additional Al-only paste (13) and (14) on Al(Si) paste (2) and (3), respectively. All other attributes of Drawing 2 are same as Drawing 1.

Drawing 3 is a top view M1 layer comprising Al-only paste (13) and (14) pads that are aligned and printed on Al(Si) paste emitter (2) and base (3) isolated fingers, which are formed on the solar cell silicon absorber (1) with surface oxide layers (7) and (8).

Drawing 4 is a top view of backplane metal (M2 layer) comprising emitter isolated fingers (10) and backplane metal base isolated fingers (11) on the dielectric backplane (9). The backplane metal (Metal 2) fingers monolithically interconnect the Al-only paste pads (13) and (14) and Al(Si) paste fingers (2) and (3) through vias in the backplane. As shown in Drawing 4, the M2 fingers may be patterned orthogonally to the M1 fingers—in other words M1 and M2 fingers are perpendicular.

Drawings 5A and 5B are diagrams showing backside levels of the solar cell—in other words top views of metal 1 layer (M1) and the dielectric backplane with vias. Drawing 6 is diagram showing a metal 2 layer (M2) backside levels of the solar cell. In a general example, metal 1 contacts base (N+) and emitter (P+) regions on the solar cell substrate through an oxide layer or stack (for example an undoped silicate glass USG, borosilicate glass BSG, and/or phosphorous silicate glass stack providing selective doping for forming base and emitter regions on an epitaxial silicon substrate). Drawing 5A is diagram showing a backside solar cell view of a metal 1 pattern (after metal 1 patterning or metal 1 print) comprising interdigitated metal 1 base fingers and metal 1 emitter fingers. Drawing 5B is diagram showing a backside solar cell view of a dielectric backplane (for example a prepreg) and patterned laser drilled vias providing metal 2 layer access/contact to underlying metal 1 layer.

Drawing 6 is diagram showing a backside solar cell view of a metal 2 layer comprising interdigitated metal 2 emitter fingers and metal 2 base fingers and corresponding metal 2 base and emitter busbars after metal 2 formation (for example by plating, thermal spray arc plasma spray, sputtering, or evaporation followed by patterning). M2 contacting the exposed areas of metal 1 through the vias in the dielectric backplane. As shown, metal 2 layer is patterned orthogonally to the underlying metal 1 layer—in other words the metal 1 fingers and metal 2 fingers are two-dimensionally perpendicular. Further, the M2 pattern may comprise substantially fewer fingers as compared to M1 and may generally be formed in a coarser pattern.

The following are considerations and suggestions for a printable Al(Si) alloy paste for high-efficiency inter-digitated backcontact (IBC) solar cells; however certain materials may not meet all of the suggestions and this list should be used as a guideline as other considerations may also determine paste characteristics. The Al(Si) paste may be screen printable or stencil printable. An Al(Si) paste for high efficiency IBC cells may have silicon content from 1% to 20% (for example 1% to 3%) to minimize spiking and intermixing of aluminum with the silicon in the underlying silicon contacts during the post anneal processing. Other key suggestions/requirements for the Al(Si) paste include maximum particle size of less than approximately 10 micrometers (for example less than approximately 2 micrometers); line resistivity less than 300 micro-ohm-cm (for example less than 30 micro-ohm-cm) after sinter anneal; no breach of Al(Si) paste through SiO2 or Al2O3, contact specific resistivity less than 0.001 ohm·cm² on both silicon base contacts (6) and silicon emitter contacts (4); high purity with trace metal concentration of Fe, Cu, Zn, Cr, and other silicon contaminants less than 500 parts per million (ppm) per element (for example less than 10 parts per million per element); good adhesion to silicon, SiO2, Al2O3, Al-paste, and backplane materials; and maximized reflectance of laser wavelengths used for laser drilling holes through the backplane materials. The Al(Si) particles may be approximately shaped as spheres or flakes, and a mixture of such shapes may be used for lowering printed and cured metal resistivity after anneal. The sinter anneal temperature may be less than approximately 650 degrees C. (and more particularly less than 600 degrees C.). Optionally, certain additives such as Ge, Co, Sr, V may be mixed with the Al(Si) paste to also further decrease paste resistivity. The printed thickness of Al(Si) paste for typical IBC cell designs is less than 30 micrometers (for example in the range of approximately 1 micrometer up to approximately 15 micrometers).

The following are considerations and suggestions for a printable Al only paste for for optional print on Al(Si) alloy paste; however certain materials may not meet all of the suggestions and this list should be used as a guideline as other considerations may also determine paste characteristics. Generally, the Al-only paste (for example the paste comprising pure Al-only particles) has similar print, adhesion, purity, and anneal suggestions/requirements as the Al(Si) alloy paste, but may have larger size particles with maximum size—for example less than 15 micrometers and more particularly in the range of approximately 5 to 10 micrometers—which may improve integration with the backplane (9) and backplane metal or Metal-2 (10) and (11). The Al-only paste may be screen printable or stencil printable. The print pattern for Al-only paste may be either pads (with the pad pattern conforming to the via drill pattern) or fingers that are aligned on the Al(Si) fingers. The Al-only fingers may help reduce the total line resistance of the printed metal fingers for Metal-1 metallization. The larger Al-only particles may further increase reflectance of laser beam at the wavelength used for laser drilling of via holes holes through the prepreg backplane material (9), and the Al-only material may enable lower contact resistivity to the overlying backplane metal (10) and (11). The resistivity requirement for Al-only pads is less than 500 micro-ohm-cm, and is higher than the Al(Si) paste because the electrical current through the Al-only pads (13) and (14) only needs to travel a relatively short distance vertically through the pads (13) and (14) and through the conductive via plugs. The printed thickness of Al-only paste may be less than approximate) 30 micrometers and more particularly less than approximately 25 micrometers. The sinter anneal temperature may be less than approximately 650 degrees C. (and more particularly less than 600 degrees C.). Other considerations/requirements for Al-only paste include:
Resistivity <500 μohm-cm After Sinter Anneal;
No Breach of Al-Only Paste Through Al2O3 or SiO2;
Contact Resistance on Al(Si) Paste <0.001 ohm/cm2;
High Purity→Trace Metal Contamination <500 ppm per Element (for example <10 ppm)
Good Adhesion to Al(Si) Paste, SiO2, Al2O3, and Backplane Materials

As used herein, the term paste describes a material which may be screen printed and the term ink describes a material which may be inkjet printed or aerosol jet printed—and both may be alloys. Thus, a paste will have a higher viscosity as compared to an ink; although in most cases the terms may be used interchangeably as either a paste alloy or an ink alloy may be applied for M1 metallization. Further, the Al(Si) alloys (inks and pastes) described herein may be formed from a combination of flake shaped Al(Si) particle alloys and spherical shaped Al(Si) particle alloys in combination with an organic solvent and an organic binder (binding) material. In some instances, the differently shaped particle—mixed flake shaped and spherical shaped particle—Al(Si) alloy may further reduce resistivity. Additionally, after application/deposition as an M1 layer, the Al(Si) alloy, for example mixed flake shaped and spherical shaped particle Al(Si) alloy, may be dried to evaporate the solvent material and then may be heated in a furnace containing an oxidizing ambient to burn off binder residue. Further, the Al(Si) alloy—for example a mixed particle shaped Al(Si) alloy—may then be thermally treated to fuse the particles together to increase alloy density.

The following process flows are provided as detailed descriptions for forming back contact solar cells with Al(Si) metallization. One having skill in the art will recognize that aspects of the described process flows and structures may be combined and/or added or deleted in numerous and various ways to form solar cells in accordance with the disclosed subject matter.

Drawing 7 shows Al(Si) paste print and anneal options. The first process flow option (20)—one burn-out anneal plus one sinter anneal—comprises print #1 (21) of Al(Si) paste emitter and base isolate fingers (2) and (3), respectively. The dry #1 (22) in clean dry air with temperature less than about 300° C. and drying time in the approximate range of 30 seconds to 5 minutes removes the solvents from the printed Al(Si) paste. Print #2 (23) is for optional Al-only paste pads (13) and (14) or Al-only fingers that are aligned on the Al(Si) paste fingers (2) and (3). Dry #2 (24) with conditions similar to dry #1 (22) removes solvents from the Al-only paste. The burn-out anneal (25) in clean dry air (or an oxidizing ambient) with temperature less than approximately 550° C. and time in the approximate range of 30 seconds to 5 minutes burns off and removes the residual organics from the printed and dried pastes. The final sinter anneal (26) in nitrogen gas or a mixture of nitrogen and hydrogen gases (i.e., a forming gas ambient) with temperature less than about 600° C. (for example in the range of greater than approximately 550° C. and less than about 600° C.) and time in the approximate range of 5 to 30 minutes coalesces the metal particles to achieve reduced cured paste resistivity without spiking or diffusion of aluminum into the silicon contacts (4) and (5), or breaching aluminum through surface oxide layers (7) and (8).

The second process flow option (30)—two burn-out and two sinter anneals for selective emitter formation—enables formation of the heavily doped contact areas (4) in silicon in conjunction with the selective emitter process and structure. Print #1 (31) is for Al(Si) paste emitter isolated fingers (2). The dry #1 (32) removes solvents from the Al(Si) paste. Burn-out anneal #2 (33) burns and removes organics from the Al(Si) paste. Sinter anneal #1 (35) in nitrogen gas or mixture of nitrogen and hydrogen gases (forming gas) with temperature less than about 650° C. and time in the approximate range of 30 seconds to 30 minutes is optimized to drive-in and diffuse aluminum into the emitter contacts areas and selectively dope the emitter silicon contact areas (4) through eutectic aluminum-silicon formation at the emitter contact regions. Print #2 is for Al(Si) paste base isolate fingers (3). Dry #2 (36) removes solvents from the Al(Si) paste base fingers (3). Print #3 (37) is for optional Al-only paste pads (13) and (14) or Al-only fingers that are aligned on the Al(Si) paste fingers (2) and (3). Dry #3 (38) removes solvents from the Al-only paste. Burn-out #2 (39) burns and removes organics from the Al(Si) paste base fingers (3) and the Al-only paste. The final sinter anneal (40) with temperature less than about 600° C. (for example less than the aluminum-silicon eutectic temperature of 577° C.) is optimized to achieve lowest paste resistivity without spiking or diffusion of aluminum into the silicon contacts (4) and (5), or breaching aluminum through surface oxide layers (7) and (8).

Drawing 8 shows a process flow diagram for manufacturing thin silicon solar cells by laser splitting and liftoff release of a thin silicon layer from a reusable silicon support wafer (for example the support wafer having a thickness in the range of approximately 300 to 1000 micrometers). A variation of this figure also applies to manufacturing thin silicon solar cells from starting silicon wafers without any liftoff release and without a reusable silicon support wafer (with the starting wafer serving as part of the final backplane-laminated solar cell). First the silicon wafer is wet cleaned (50) in for example a sodium hydroxide (KOH) solution followed by a mixed solution of hydrofluoric acid (HF) and hydrochloric acid (HCl). This initial etch process may also serve as a Saw Damage Removal (SDR) process step. Then the cell backside is processed (51) forming the backside oxide passivation layers (7)(8), and the patterned doped areas: selective emitter contact area (4), field emitter area (5), base contact area (6); and then followed by Al(Si) paste (2)(3), and optional Al-only paste (13)(14) patterned prints and anneals (20) and (30). Drawing 14 summarizes the cell backside process flow options (51). When the cell backside processing is complete, then a dielectric backplane (9) is aligned, attached, laminated, and cured onto the cell backside.

In case of making a solar cell using a lift-off release from a reusable support wafer (template), a laser may then trench to define the edge release borders. Permeable, scanning lasers are then used to split the thin silicon layer from the silicon support wafer. The thin silicon cell is then lifted and released from the reusable silicon support wafer, and the edges of the silicon cell and backplane may be laser cut and trimmed. After release the silicon support wafer is reused and may be reconditioned (53) by for example grinding and polishing the edges and/or surface followed by cleaning. The silicon support wafer may go through several reuse cycles (58). After release of the thin silicon (59), the silicon cell frontside is processed as described next. In case of making a solar cell from a starting wafer without using a lift-off release and without a reusable support wafer (template), the above laser splitting, lift-off release, and edge trim processes are not performed and we proceed directly from the backplane lamination process to the silicon cell frontside processing as described next.

The silicon cell frontside is wet etched/textured (54) by for example HF dip and DI water rinse to first remove surface oxide, and then a hot 50° C. to 100° C. mixed solution of KOH and surfactant for silicon etch and random pyramidal surface texturing, followed by rinse and clean in for example a mixed solution of HF and HCl with a final DI water rinse and dry. The silicon cell frontside is then coated by low-temperature (≦300° C.) PECVD thin films for passivation and antireflection (55). The first thin film may be an intrinsic (undoped) amorphous silicon (α-Si:H) or α-SiOx:H or α-SiOxCy:H of thickness less than 10 nanometers for good surface passivation, e.g. heterojunction and low Dit. The second layer thin film may be n-type (phosphorus) doped amorphous silicon (α-Si:H) or α-SiOx:H or α-SiOxCy:H of thickness less than 10 nanometers for enhanced field effect passivation and stable passivation. The capping may be amorphous SiOxNy:H or dual layer SiOx:H on SiNx:H and with thicknesses and refractive indices that are optimized for minimized reflectance. When the cell frontside processing is complete, the backplane is processed (56) by laser to drill via holes that open up contacts to the embedded Al(Si) and Al-only paste. Patterned metallization (Metal 2) onto the dielectric backplane and via holes (57) creates a second metal layer to interconnect and collect current from the embedded Al(Si) and Al-only paste. Drawing 13 summarizes the backplane metallization process flow options (57). The thin silicon cell with backplane may then process to final laser edge trim, test and sorting. Note the thin silicon cell is mechanically supported by a silicon support wafer through the process steps before release, and mechanically supported with a dielectric backplane (9) through the process steps after release.

Drawing 9 shows a process flow diagram for manufacturing thin silicon solar cells by laser splitting and liftoff release of an epitaxial silicon layer from a silicon support wafer (for example a thickness in the range of 300 to 1000 micrometers). The process flow starts the same as Drawing 8 with wet clean of the silicon support wafer (50). Then an epitaxial thin film is deposited with total thickness than 80 micrometers (71). The epitaxial layer may first be deposited with thickness less than 15 micrometers and n-type doping concentration approximately in the range of 1×10¹⁷ cm⁻³ to 1×10¹⁹ cm⁻³ optimized to make an optional in-situ frontside surface field (FSF) in the thin silicon cell. On the FSF epitaxial layer, the epitaxial process is switched for optimized n-type base doping concentration approximately in the range of 8×10¹⁴ cm⁻³ to 3×10¹⁶ cm⁻³. The total thickness of the epitaxial layers is less than about 80 micrometers. After epitaxial deposition (71), the process flow is the same as shown in Diagram 8.

Drawing 10 shows a process flow diagram for manufacturing thin silicon solar cells by laser splitting and liftoff release of an epitaxial silicon layer from a porous silicon layer. The process flow starts the same as Drawing 8 and 9 with wet clean of the silicon support wafer (50). Then a bilayer of porous silicon is formed (70) on one side of the silicon support wafer, before epitaxial deposition (71) of the absorber layer. The bilayer of porous silicon defines the plane from which the epitaxial layer will be released from the silicon support wafer. The porous silicon bilayer also may enhance the absorption of laser energy that is used in the laser splitting (52) of the thin silicon layer. The subsequent process steps for Drawing 10 are the same as Drawing 9.

Drawing 11 shows a process flow diagram for manufacturing thin silicon solar cells by mechanical liftoff release of an epitaxial silicon layer from a porous silicon layer. Drawing 11 is the same as Drawing 10 except for step (72) in which the thin silicon cell is mechanically lifted and released from the silicon support wafer. For this process flow the thickness and porous density of the porous silicon bilyaer is optimized to enable a mechanical release of the epitaxial silicon layer.

Drawing 12 shows a process flow diagram for manufacturing thin silicon solar cells by frontside silicon etch and texture of a silicon wafer (for example a thickness in the range of approximately 100 to 200 micrometers. Drawing 12 is the same as Drawing 8 except for step (73) in which there is no splitting of a thin silicon layer. The process step (54) for the process flow in Drawing 12 is optimized to etch the frontside of the silicon wafer down to a thin silicon thickness of, for example, 30 to 70 micrometers that is optimized for maximum cell efficiency.

Drawing 13 shows four optional backplane metallization process flows. Process flow option #1 (57A) uses a printable metal paste. The process flow starts with an optional wet or dry etch (84) to clean the via holes. The clean may be designed to remove for example organic backplane residues left from laser drill process (56). The clean also may be designed to remove for example surface oxide from the Al(Si) paste (2) and (3) or the Al-only paste (13) and (14). Then a solder metal paste is directly printed on the backplane (9) and via openings. The printed pattern of backplane metal isolated emitter (10) and base (11) fingers is aligned onto the backplane and via openings to interconnect the underlying emitter and base Al(Si) and Al-only paste fingers. The metal solder paste may be comprised of Al(Zn) (aluminum-zinc) alloy particles or Cu(Sn) (copper-tin) alloy particles. For lower contact resistance, the metal solder paste also may have an added chlorine-containing flux to reduce surface oxide on the underlying Al(Si) or Al-only paste. A final anneal (86) with temperature less than 300 C is done to sinter the metal solder paste for low resistance. The final anneal (86) also may improve the surface passivation by the frontside SiOxCy:H thin films (12). Process flow option #2 (57B) uses a thermal spray to apply the backplane metal. The process flow starts the same as (57A) with an optional wet or dry etch (84) to clean the via holes. Then a thermal spray process is used to directly pattern and align Al(Zn) (aluminum-zinc) alloy metal onto the backplane and via openings. A shadow mask may be used to directly pattern the backplane metal isolated emitter (10) and base (11) fingers. An optional final anneal (86) may improve frontside surface passivation. Process flow option #3 (57C) uses a PVD layer for backplane metallization. The PVD processing (88) may start with a sputter etch to remove surface oxide from the Al(Si) or Al-only paste that is inside the via holes. Then a PVD bilayer is deposited comprising aluminum with thickness 2 to 5 micrometers followed by nickel-vanadium (NiV) with thickness 10 to 400 nanometers. Alternatively a PVD bilayer of copper (Cu) is deposited with thickness 1 to 3 micrometers followed by tin (Sn) with thickness 10 to 400 nanometers. The thicker PVD metals may be evaporated and the thinner PVD metals may be sputtered. After PVD an optional anneal (86) may be done to improve frontside passivation. The PVD metal layers are then patterned (89) by laser ablation from the dielectric backplane or by using a sacrificial mask and wet etch to form the backplane metal isolated emitter (10) and base (11) fingers. Process flow option #4 uses a PVD seed layer and plating for backplane metallization. The PVD processing (90) may start with a sputter etch. A PVD bilayer is then deposited comprising of Al with thickness 0.1 to 2 micrometers followed by NiV with thickness 10 to 100 nanometers. After PVD an optional anneal (86) may be done to improve frontside passivation. Then the metal is patterned (91) by laser ablation from the backplane or by application of a patterned sacrificial dielectric mask, which will be removed later. A sacrificial dielectric barrier layer (92) is applied on the cell frontside, before the electroplating (93) of a copper layer (thickness 10 to 50 micrometers) and a tin capping layer (thickness less than 1 micrometer). Finally a wet etch selectively removes the sacrificial layers (94).

Drawing 14 shows a table summary of the cell backside process flow options (51) for selective emitter. The table summary categorizes by dopant source options (100), junction isolation options (101), Al(Si) paste print and anneal options (102), and number of process tools in the process flow (103). The dopant source options (100) are further categorized for the field emitter area (104), selective emitter contact area (105), and base contact area (106). The table lists the process flow title (129) together with a flow option number (128), which are each described in more detail in subsequent drawings.

Drawing 15 shows cell backside process flow option 130A for an ex-situ emitter with APCVD boron-doped oxide and abutted junction (116). For this process flow option 130A the selective emitter contact area is doped by hot laser ablation of the APCVD boron-doped oxide (109), and the base contact area is doped by furnace anneal of an APCVD phosphorus-doped oxide (113). The process flow starts with atmospheric pressure chemical vapor deposition (APCVD) of boro-silicate glass (BSG) or boron-doped Al2O3, followed by an undoped oxide capping layer of undoped silicate glass (USG) or undoped Al2O3 (150). The undoped capping layer protects the underlying doped layer from a chemical reaction with the moisture in the atmosphere. The APCVD boron oxide layer stack is then patterned by pulsed laser cold ablation to open the base contact areas on the silicon (151). Damage of the silicon may be reduced by an optimized laser process with pulse time from a femtosecond to several picoseconds. An APCVD phospho-silicate glass (PSG) or phosphorus-doped Al2O3, followed by an undoped layer is then deposited on both base contact openings and the boron doped layer stack (152). The cell is then annealed and oxidized in a furnace with a temperature and time to drive-in boron into the field emitter area and phosphorus into the base contact area (153). The thermal oxidation may enhance backside surface pasivation by the APCVD layers. A boron concentration from 0.5% to 3% in the APCVD boron oxide layer is optimized to form a sheet resistance of 100 to 300 ohm/square in the field emitter area after the thermal diffusion. A phosphorus concentration from 5% to 10% in the phosphorus APCVD oxide layer is optimized to form a sheet resistance less than 20 ohm/square in the base contact areas after the thermal diffusion. Patterned and pulsed laser hot ablations of the oxide stack is next done to selectively boron dope and open the emitter contact areas on the silicon (154). The hot laser ablation process is optimized to drive-in boron and form a sheet resistance less than 20 ohm/square in the emitter contact areas. Patterned and pulsed laser cold ablations of the oxide stack are done to reopen the base contact areas (155). The cell backside processing is completed by Al(Si) print and anneal option #1 (20) as shown in Drawing 7. The Al(Si) paste makes contact to both emitter and base and enables a cell backside reflector.

Drawing 16 shows cell backside process flow option 130B for an ex-situ emitter with APCVD boron-doped oxide and abutted junction (116). For this process flow option 130B the selective emitter contact area is doped by furnace anneal of a second boron-doped APCVD oxide layer with high boron concentration (110), and the base contact area is doped by furnace anneal of an APCVD phosphorus-doped oxide (113). The process flow starts with APCVD of a boron-doped oxide layer with boron concentration 0.5% to 3% that is optimized for doping the field emitter area, followed by an undoped oxide capping layer (150). The APCVD boron oxide layer stack is then patterned by pulsed laser cold ablation to open the emitter contact areas on the silicon (163). The second APCVD boron-doped oxide layer is deposited with higher boron concentration 5% to 10% that is optimized for doping the emitter contact areas (156). The APCVD boron oxide layer stack is then patterned by pulsed laser cold ablation to open the base contact areas on the silicon (151), and an APCVD phosphorus-doped oxide layer is deposited on both base contact openings and the boron oxide layer stack (152). The cell is then annealed and oxidized in a furnace with a temperature and time to drive-in boron into the silicon field emitter area and silicon emitter contact area, and phosphorus into the silicon base contact area (157). The furnace anneal and the APCVD doping concentrations are optimized to form a sheet resistance of 100 to 300 ohm/square in the silicon field emitter area, and a sheet resistance less than 20 ohm/square in both the silicon emitter and base contact areas after the thermal diffusion. Patterned and pulsed laser cold ablations of the oxide stack are done to reopen the emitter contact areas and reopen the base contact areas (158). The cell backside processing is completed by Al(Si) print and anneal option #1 (20) as shown in Drawing 7.

Drawing 17 shows cell backside process flow option 130C for an ex-situ emitter with APCVD boron-doped oxide and abutted junction (116). For this process flow option 130C the selective emitter contact area is doped by laser anneal of the Al(Si) paste (111), and the base contact area is doped by furnace anneal of an APCVD phosphorus-doped oxide (113). The process flow starts with APCVD of a boron oxide layer (150), pulsed laser cold ablation of oxide to open base contact areas (151), APCVD of a phosphorus oxide layer (152), and furnace anneal and oxidation for base contact doping and field emitter doping formation (153). Then patterned and pulsed laser cold ablations of the oxide stack are done to open the emitter contact areas on the silicon and reopen the base contact area on the silicon (159). The Al(Si) print and anneal option #1 processing (20) is next done as shown in Drawing 7. The cell backside processing is completed by selectively laser annealing the Al(Si) emitter fingers to drive-in aluminum into the silicon and form the selective emitter (160). The laser anneal process is optimized to drive-in aluminum and form a sheet resistance less than 20 ohm/square in the emitter contact areas.

Drawing 18 shows cell backside process flow option 130D for an ex-situ emitter with APCVD boron-doped oxide and abutted junction (116). For this process flow option 130D the selective emitter contact area is doped by a furnace sinter anneal of the Al(Si) paste (112), and the base contact area is doped by furnace anneal of an APCVD phosphorus-doped oxide (113). The process flow starts with APCVD of a boron oxide layer (150), pulsed laser cold ablation of oxide to open base contact areas (151), APCVD of a phosphorus oxide layer (152), and furnace anneal and oxidation for base contact doping and field emitter doping formation (153). Then patterned and pulsed laser cold ablations of the oxide stack are done to open the emitter contact areas on the silicon and reopen the base contact area on the silicon (159). The Al(Si) print and anneal option #2 processing (30) is next done as shown in Drawing 7. The sinter #1 anneal (34) is optimized to drive-in aluminum and form a sheet resistance less than 20 ohm/square in the emitter contact areas.

Drawing 19 shows cell backside process flow option 130E for an ex-situ emitter with APCVD boron-doped oxide and abutted junction (116). For this process flow option 130E the selective emitter contact area is doped by hot laser ablation of the APCVD boron-doped oxide (109), and the base contact area is doped by furnace anneal of a printed phosphosilicate glass (PSG) paste (115). The process flow starts with a direct patterned and aligned print of PSG paste isolated fingers on the base contact areas of the silicon (162). The width of the printed PSG paste fingers is less than 150 micrometers. Optional tools for direct pattern printing include screen print, inkjet print, aerosol jet print, or laser transfer print. After print the PSG paste is dried and annealed in air to burn-out the organic binder materials. Next an APCVD boron-doped oxide layer is deposited (150), followed by a furnace anneal and oxidation for base contact doping and field emitter doping formation (153). The phosphorus concentration in the PSG paste is optimized for a sheet resistance less than 20 ohm/square in the silicon base contact areas after the thermal diffusion. Patterned and pulsed laser hot ablations of the oxide stack is next done to selectively boron dope and open the emitter contact areas on the silicon (154). Patterned and pulsed laser cold ablations of the oxide stack are done to open the base contact areas (151). The cell backside processing is completed by Al(Si) print and anneal option #1 (20) as shown in Drawing 7.

Drawing 20 shows cell backside process flow option 130F for an ex-situ emitter with APCVD boron-doped oxide and abutted junction (116). For this process flow option 130F the selective emitter contact area is doped by furnace anneal of a second boron-doped APCVD oxide layer with high boron concentration (110), and the base contact area is doped by furnace anneal of a printed phosphosilicate glass (PSG) paste (115). The process flow starts with a direct patterned and aligned print of PSG paste isolated fingers on the base contact areas of the silicon (162), followed by APCVD of a boron-doped oxide layer with boron concentration 0.5% to 3% that is optimized for doping the field emitter area (150). The APCVD boron oxide layer stack is then patterned by pulsed laser cold ablation to open the emitter contact areas on the silicon (163). The second APCVD boron-doped oxide layer is deposited with higher boron concentration that is optimized for doping the emitter contact areas (156). The cell is then annealed and oxidized in a furnace with a temperature and time to drive-in boron into the silicon field emitter area and silicon emitter contact area, and phosphorus into the silicon base contact area (157). Patterned and pulsed laser cold ablations of the oxide stack are done to reopen the emitter contact areas and open the base contact areas (164). The cell backside processing is completed by Al(Si) print and anneal option #1 (20) as shown in Drawing 7.

Drawing 21 shows cell backside process flow option 130G for an ex-situ emitter with APCVD boron-doped oxide and abutted junction (116). For this process flow option 130G the selective emitter contact area is doped by laser anneal of the Al(Si) paste (111), and the base contact area is doped by furnace anneal of a printed phosphosilicate glass (PSG) paste (115). The process flow starts with a direct patterned and aligned print of PSG paste isolated fingers on the base contact areas of the silicon (162), followed by APCVD of a boron-doped oxide layer that is optimized for doping the field emitter area (150). A furnace anneal and oxidation then drives in phosphorus for base contact doping and boron for field emitter doping formation (153). Then patterned and pulsed laser cold ablations of the oxide stack are done to open the emitter contact areas on the silicon and open the base contact areas on the silicon (165). The Al(Si) print and anneal option #1 processing (20) is next done as shown in Drawing 7. The cell backside processing is completed by selectively laser annealing the Al(Si) emitter fingers to drive-in aluminum into the silicon and form the selective emitter (160).

Drawing 22 shows cell backside process flow option 130H for an ex-situ emitter with APCVD boron-doped oxide and abutted junction (116). For this process flow option 130H the selective emitter contact area is doped by a furnace sinter anneal of the Al(Si) paste (112), and the base contact area is doped by furnace anneal of a printed phosphosilicate glass (PSG) paste (115). The process flow starts with a direct patterned and aligned print of PSG paste isolated fingers on the base contact areas of the silicon (162), followed by APCVD of a boron-doped oxide layer that is optimized for doping the field emitter area (150). A furnace anneal and oxidation then drives in phosphorus for base contact doping and boron for field emitter doping formation (153). Then patterned and pulsed laser cold ablations of the oxide stack are done to open the emitter contact areas on the silicon and open the base contact areas on the silicon (165). The Al(Si) print and anneal option #2 processing (30) is next done as shown in Drawing 7. The sinter #1 anneal (34) is optimized to drive-in aluminum and form a sheet resistance less than 20 ohm/square in the emitter contact areas.

Drawing 23 shows cell backside process flow option 131A for an ex-situ emitter with APCVD boron-doped oxide and isolated junction by APCVD undoped oxide (117). For this process flow option 131A the selective emitter contact area is doped by hot laser ablation of the APCVD boron-doped oxide (109), and the base contact area is doped by furnace anneal of an APCVD phosphorus-doped oxide (113). The process flow starts with APCVD of a boron oxide layer (150). Then patterned and pulsed laser cold ablations of the oxide stack are done to open the emitter-base isolation areas on silicon (166). Then an undoped APCVD oxide layer of either undoped silicate glass (USG) or undoped Al2O3 is deposited (167). The undoped oxide layer will be a passivation layer and a barrier layer to prevent drive-in diffusion of dopants into the emitter-base isolation areas on silicon. The APCVD oxide layer stack is then patterned by pulsed laser cold ablation to open the base contact areas on the silicon (151), and an APCVD phosphorus-doped oxide layer is deposited (152). A furnace anneal and oxidation then drives in phosphorus for base contact doping and boron for field emitter doping formation (153), leaving the base-emitter isolation areas on silicon undoped. Patterned and pulsed laser hot ablations of the oxide stack is next done to selectively boron dope and open the emitter contact areas on the silicon (154). The APCVD boron oxide layer stack is then patterned by pulsed laser cold ablation to reopen the base contact areas on the silicon (155). The cell backside processing is completed by Al(Si) print and anneal option #1 (20) as shown in Drawing 7.

Drawing 24 shows cell backside process flow option 131B for an ex-situ emitter with APCVD boron-doped oxide and isolated junction by APCVD undoped oxide (117). For this process flow option 131B the selective emitter contact area is doped by furnace anneal of a second boron-doped APCVD oxide layer with high boron concentration (110), and the base contact area is doped by furnace anneal of an APCVD phosphorus-doped oxide (113). The process flow starts with APCVD of a boron oxide layer (150), and is then patterned by pulsed laser cold ablation to open the emitter contact areas on the silicon (163). The second APCVD boron-doped oxide layer is deposited with higher boron concentration that is optimized for doping the emitter contact areas (156). Then patterned and pulsed laser cold ablations of the oxide stack are done to open the emitter-base isolation areas on silicon (166). Next an undoped APCVD oxide layer of is deposited (167), followed by patterned and pulsed laser cold ablation of the oxide stack to open the base contact areas on the silicon (151). An APCVD phosphorus-doped oxide layer is deposited on both base contact openings and the boron oxide layer stack (152). The cell is then annealed and oxidized in a furnace with a temperature and time to drive-in boron into the silicon field emitter area and silicon emitter contact area, and phosphorus into the silicon base contact area (157), leaving the base-emitter isolation areas on silicon undoped. Patterned and pulsed laser cold ablations of the oxide stack are done to reopen the emitter contact areas and reopen the base contact areas (158). The cell backside processing is completed by Al(Si) print and anneal option #1 (20) as shown in Drawing 7.

Drawing 25 shows cell backside process flow option 131C for an ex-situ emitter with APCVD boron-doped oxide and isolated junction by APCVD undoped oxide (117). For this process flow option 131C the selective emitter contact area is doped by laser anneal of the Al(Si) paste (111), and the base contact area is doped by furnace anneal of an APCVD phosphorus-doped oxide (113). The process flow starts with APCVD of a boron oxide layer (150). Then patterned and pulsed laser cold ablations of the oxide stack are done to open the emitter-base isolation areas on silicon (166). Then an undoped APCVD oxide layer is deposited (167), and the APCVD oxide layer stack is patterned by pulsed laser cold ablation to open the base contact areas on the silicon (151). After an APCVD phosphorus-doped oxide layer is deposited (152), a furnace anneal and oxidation then drives in phosphorus for base contact doping and boron for field emitter doping formation (153), leaving the base-emitter isolation areas on silicon undoped. Then patterned and pulsed laser cold ablations of the oxide stack are done to open the emitter contact areas on the silicon and reopen the base contact area on the silicon (159). The Al(Si) print and anneal option #1 processing (20) is next done as shown in Drawing 7. The cell backside processing is completed by selectively laser annealing the Al(Si) emitter fingers to drive-in aluminum into the silicon and form the selective emitter (160).

Drawing 26 shows cell backside process flow option 131D for an ex-situ emitter with APCVD boron-doped oxide and isolated junction by APCVD undoped oxide (117). For this process flow option 131C the selective emitter contact area is doped by a furnace sinter anneal of the Al(Si) paste (112), and the base contact area is doped by furnace anneal of an APCVD phosphorus-doped oxide (113). The process flow is same as process flow option 131C except for the last two steps are replaced by Al(Si) print and anneal option #2 processing (30) as shown in Drawing 7. The sinter #1 anneal (34) is optimized to drive-in aluminum and form a sheet resistance less than 20 ohm/square in the emitter contact areas.

Drawing 27 shows cell backside process flow option 132A for an ex-situ emitter with APCVD boron-doped oxide and isolated junction by printed USG (118). For this process flow option 132A the selective emitter contact area is doped by hot laser ablation of the APCVD boron-doped oxide (109), and the base contact area is doped by furnace anneal of an APCVD phosphorus-doped oxide (113). The process flow starts with a direct patterned and aligned print of USG paste isolated fingers on the base contact areas of the silicon (168). The width of the printed USG fingers is from 50 to 300 micrometers and is optimized to create the emitter-base isolation areas on silicon. Optional tools for direct pattern printing include screen print, inkjet print, aerosol jet print, or laser transfer print. After print the USG paste is dried and annealed in air to burn-out the organic binder materials. After USG print, the process flow is the same as process flow option 130A. The USG paste is a barrier layer during the furnace anneal to prevent drive-in diffusion of dopants into the emitter-base isolation areas on silicon, and the USG paste after anneal is the passivation layer on the emitter-base isolation areas on silicon.

Drawing 28 shows cell backside process flow option 132B for an ex-situ emitter with APCVD boron-doped oxide and isolated junction by printed USG (118). For this process flow option 132B the selective emitter contact area is doped by furnace anneal of a second boron-doped APCVD oxide layer with high boron concentration (110), and the base contact area is doped by furnace anneal of an APCVD phosphorus-doped oxide (113). The process flow starts with a direct patterned and aligned print of USG paste isolated fingers with width from 50 to 300 micrometers on the base contact areas of the silicon (168). After USG print, the process flow is the same as process flow option 130B. The USG paste is a barrier layer during the furnace anneal to prevent drive-in diffusion of dopants, and defines the emitter-base isolation areas on silicon.

Drawing 29 shows cell backside process flow option 132C for an ex-situ emitter with APCVD boron-doped oxide and isolated junction by printed USG (118). For this process flow option 132C the selective emitter contact area is doped by laser anneal of the Al(Si) paste (111), and the base contact area is doped by furnace anneal of an APCVD phosphorus-doped oxide (113). The process flow starts with a direct patterned and aligned print of USG paste isolated fingers with width from 50 to 300 micrometers on the base contact areas of the silicon (168). After USG print, the process flow is the same as process flow option 130C. The USG paste is a barrier layer during the furnace anneal to prevent drive-in diffusion of dopants, and defines the emitter-base isolation areas on silicon.

Drawing 30 shows cell backside process flow option 132D for an ex-situ emitter with APCVD boron-doped oxide and isolated junction by printed USG (118). For this process flow option 132D the selective emitter contact area is doped by a furnace sinter anneal of the Al(Si) paste (112), and the base contact area is doped by furnace anneal of an APCVD phosphorus-doped oxide (113). The process flow starts with a direct patterned and aligned print of USG paste isolated fingers with width from 50 to 300 micrometers on the base contact areas of the silicon (168). After USG print, the process flow is the same as process flow option 130D. The USG paste is a barrier layer during the furnace anneal to prevent drive-in diffusion of dopants, and defines the emitter-base isolation areas on silicon.

Drawing 31 shows cell backside process flow option 132E for an ex-situ emitter with APCVD boron-doped oxide and isolated junction by printed USG (118). For this process flow option 132E the selective emitter contact area is doped by hot laser ablation of the APCVD boron-doped oxide (109), and the base contact area is doped by furnace anneal of a printed PSG paste (115). The process flow starts with a direct patterned and aligned print of PSG paste isolated fingers with width less than 150 micrometers on the base contact areas of the silicon (169). The PSG paste is dried after print. Then USG paste lines are aligned and printed onto PSG fingers (170). The print of the USG paste lines is optimized for minimum thickness and width to fully encapsulate the PSG paste lines. The USG paste is then dried, and both the PSG and USG pastes are annealed in air to burn-out the organic binder materials. The width of the emitter-base isolation areas on silicon is defined by the extra USG paste line width that extends beyond the edges of the underlying PSG paste. After print and anneal, the process flow is the same as process flow option 130E except for first step (162). The USG paste is a barrier layer during the furnace anneal and prevents drive-in diffusion of dopants into the emitter-base isolation areas.

Drawing 32 shows cell backside process flow option 132F for an ex-situ emitter with APCVD boron-doped oxide and isolated junction by printed USG (118). For this process flow option 132F the selective emitter contact area is doped by furnace anneal of a second boron-doped APCVD oxide layer with high boron concentration (110), and the base contact area is doped by furnace anneal of a printed PSG paste (115). The process flow starts with a direct patterned and aligned print of PSG paste isolated fingers on the base contact areas of the silicon (169). The PSG paste is dried after print, and then USG paste lines are aligned and printed to encapsulate the PSG fingers (170). The USG paste is then dried, and both the PSG and USG pastes are annealed in air to burn-out the organic binder materials. The width of the emitter-base isolation areas on silicon is defined by the extra USG paste line width that extends beyond the edges of the underlying PSG paste. After print and anneal, the process flow is the same as process flow option 130F except for first step (162). The USG paste is a barrier layer during the furnace anneal and prevents drive-in diffusion of dopants into the emitter-base isolation areas.

Drawing 33 shows cell backside process flow option 132G for an ex-situ emitter with APCVD boron-doped oxide and isolated junction by printed USG (118). For this process flow option 132G the selective emitter contact area is doped by laser anneal of the Al(Si) paste (111), and the base contact area is doped by furnace anneal of a printed PSG paste (115). The process flow starts with a direct patterned and aligned print of PSG paste isolated fingers on the base contact areas of the silicon (169). The PSG paste is dried after print, and then USG paste lines are aligned and printed to encapsulate the PSG fingers (170). The USG paste is then dried, and both the PSG and USG pastes are annealed in air to burn-out the organic binder materials. The width of the emitter-base isolation areas on silicon is defined by the extra USG paste line width that extends beyond the edges of the underlying PSG paste. After print and anneal, the process flow is the same as process flow option 130G except for first step (162). The USG paste is a barrier layer during the furnace anneal and prevents drive-in diffusion of dopants into the emitter-base isolation areas.

Drawing 34 shows cell backside process flow option 132H for an ex-situ emitter with APCVD boron-doped oxide and isolated junction by printed USG (118). For this process flow option 132H the selective emitter contact area is doped by a furnace sinter anneal of the Al(Si) paste (112), and the base contact area is doped by furnace anneal of a printed PSG paste (115). The process flow starts with a direct patterned and aligned print of PSG paste isolated fingers on the base contact areas of the silicon (169). The PSG paste is dried after print, and then USG paste lines are aligned and printed to encapsulate the PSG fingers (170). The USG paste is then dried, and both the PSG and USG pastes are annealed in air to burn-out the organic binder materials. The width of the emitter-base isolation areas on silicon is defined by the extra USG paste line width that extends beyond the edges of the underlying PSG paste. After print and anneal, the process flow is the same as process flow option 130H except for first step (162). The USG paste is a barrier layer during the furnace anneal and prevents drive-in diffusion of dopants into the emitter-base isolation areas.

Drawing 35 shows cell backside process flow option 133A for an in-situ emitter from boron-doped silicon epitaxy (108) and isolated junction by laser ablation of boron-doped silicon (119). For this process flow option 133A the selective emitter contact area is doped by hot laser ablation of the APCVD boron-doped oxide (109), and the base contact area is doped by hot laser ablation of the APCVD phosphorus-doped oxide (114). The process flow starts with epitaxial deposition of an optional in-situ phosphorus-doped silicon layer with doping concentration 1×10¹⁷ cm⁻³ to 1×10¹⁹ cm⁻³ and thickness less than 15 micrometers, which will function as a front surface field in the final cell. Then a phosphorus-doped epitaxial base layer with doping concentration 8×10¹⁴ cm⁻³ to 3×10¹⁶ cm⁻³ is deposited to increase the total epitaxial thickness to less than 80 micrometers. A final in-situ boron-doped field emitter is deposited with boron concentration from 1×10¹⁸ cm⁻³ to 1×10¹⁹ cm⁻³ and thickness less than one micrometer (180). Then an APCVD boron-doped oxide layer is deposited with boron concentration 5% to 10% that is optimized for doping the emitter contact areas (150). Then patterned and pulsed laser cold ablations of the oxide stack and boron-doped silicon are done to open the emitter-base isolation areas on silicon (190). The ablated silicon thickness is less than one micrometer exposing the phosphorus-doped base silicon. An APCVD phosphorus-doped oxide is then deposited onto the boron-doped oxide and the silicon openings (152). Patterned and pulsed laser hot ablations of the oxide stack is next done to selectively boron dope and open the emitter contact areas on the silicon (154). Patterned and pulsed laser hot ablations of the phosphorus-doped oxide stack is done to selectively phosphorus dope and open the base contact areas on the previously ablated silicon areas (200). The hot laser ablation processes are optimized to drive-in boron and phosphorus to form a sheet resistance less than 20 ohm/square in both the emitter and base contact areas. The cell backside processing is completed by Al(Si) print and anneal option #1 (20) as shown in Drawing 7.

Drawing 36 shows cell backside process flow option 133B for an in-situ emitter from boron-doped silicon epitaxy (108) and isolated junction by laser ablation of boron-doped silicon (119). For this process flow option 133B the selective emitter contact area is doped by laser anneal of the Al(Si) paste (111), and the base contact area is doped by hot laser ablation of the APCVD phosphorus-doped oxide (114). The process flow starts with epitaxial silicon deposition of the optional front surface field layer, followed by the base layer and in-situ emitter layer (180). Then an APCVD undoped oxide layer is deposited (167). Next patterned and pulsed laser cold ablations of the oxide stack and boron-doped silicon are done to open the emitter-base isolation areas on silicon (190). The ablated silicon thickness is less than one micrometer exposing the phosphorus-doped base silicon. An APCVD phosphorus-doped oxide is then deposited onto the APCVD oxide and the silicon openings (152). The APCVD oxide layer stack is then patterned by pulsed laser cold ablation to open the emitter contact areas on the silicon (163). Patterned and pulsed laser hot ablations of the phosphorus-doped oxide stack is done to selectively phosphorus dope and open the base contact areas on the previously ablated silicon areas (200). The hot laser ablation process is optimized to drive-in phosphorus to form a sheet resistance less than 20 ohm/square in the base contact areas. The Al(Si) print and anneal option #1 processing (20) is next done as shown in Drawing 7. The cell backside processing is completed by selectively laser annealing the Al(Si) emitter fingers to drive-in aluminum into the silicon and form the selective emitter (160). The laser anneal process is optimized to drive-in aluminum and form a sheet resistance less than 20 ohm/square in the emitter contact areas.

Drawing 37 shows cell backside process flow option 133C for an in-situ emitter from boron-doped silicon epitaxy (108) and isolated junction by laser ablation of boron-doped silicon (119). For this process flow option 133C the selective emitter contact area is doped by a furnace sinter anneal of the Al(Si) paste (112), and the base contact area is doped by hot laser ablation of the APCVD phosphorus-doped oxide (114). The process flow is same as process flow option 133B except for the last two steps are replaced by Al(Si) print and anneal option #2 processing (30) as shown in Drawing 7. The sinter #1 anneal (34) is optimized to drive-in aluminum and form a sheet resistance less than 20 ohm/square in the emitter contact areas.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A back contact solar cell structure, comprising:
a first aluminum-silicon alloy layer on a backside surface of a semiconductor solar cell substrate, said first aluminum-silicon alloy layer comprising base electrodes and emitter electrodes connected to base regions and emitter regions on said semiconductor solar cell substrate;
an electrically insulating backplane layer on said first aluminum-silicon alloy, said backplane layer comprising via holes to access said first aluminum silicon alloy layer, said via holes drilled through said backplane layer and stopped at said first aluminum-silicon alloy layer at selective positions without punching through said first aluminum-silicon alloy layer, to form base contacts and emitter contacts to said first metal layer; and
a second metal layer of electrically conductive metal on said electrically insulating backplane layer, said second metal layer electrically contacted to said first aluminum silicon alloy layer through said via holes.

2. An interdigitated back-contact solar cell structure, comprising:
a crystalline semiconductor absorber layer comprising:
a surface passivation and antireflection coating layer on the frontside of said semiconductor absorber;
a thicker lightly doped n-type base layer and a thinner heavily doped p-type emitter junction on the backside of said semiconductor absorber; and
a backside structure, said backside structure comprising:
a patterned backside dielectric dopant source and surface passivation structure with base and emitter contact openings;
a first interdigitated base and emitter metallization layer comprising a plurality of direct-write printed silicon-containing aluminum fingers directly on said patterned backside dielectric dopant source and passivation structure and contacting said base and emitter regions through said base and emitter contact openings;
an electrically insulating backplane layer attached to said solar cell structure on said patterned backside dielectric dopant source and surface passivation structure and said first patterned interdigitated base and emitter metallization layer, said backplane layer comprising a plurality of via holes landing on said first interdigitated base and emitter metallization layer; and
a second interdigitated base and emitter metallization layer formed on said electrically insulating backplane layer, said second interdigitated base and emitter metallization layer comprising patterned conductor fingers aligned substantially orthogonal to said first interdigitated base and emitter metallization layer.

3. The interdigitated back-contact solar cell structure of claim 2, wherein said first interdigitated base and emitter metallization layer has a higher number of base and emitter metallization fingers compared to said second interdigitated base and emitter metallization layer.

4. The interdigitated back-contact solar cell structure of claim 2, wherein said semiconductor absorber frontside passivation and antireflection coating layer comprises a combination of at least one of an amorphous silicon hydrogen compound, an amorphous silicon nitride compound, and an amorphous silicon dioxide compound.

5. The interdigitated back-contact solar cell structure of claim 2, wherein said semiconductor absorber frontside passivation and antireflection coating layer comprises a combination of at least one of an amorphous silicon-oxide compound and an amorphous silicon nitride compound.

6. The interdigitated back-contact solar cell structure of claim 2, wherein said semiconductor absorber frontside passivation and antireflection coating layer comprises a combination of at least one of an amorphous silicon-carbide compound and an amorphous silicon nitride compound.

7. The interdigitated back-contact solar cell structure of claim 2, wherein said semiconductor absorber frontside passivation and antireflection coating layer comprises a combination at least one layer of amorphous silicon compound with one or a combination of hydrogen, oxygen, and carbon atoms, and least one layer of amorphous silicon nitride and amorphous silicon dioxide compound.

8. The interdigitated back-contact solar cell structure of claim 2, wherein said semiconductor absorber frontside passivation and antireflection coating layer comprises a combination of amorphous silicon-hydrogen compound and amorphous silicon nitride-hydrogen compound.

9. A method for forming an interdigitated back-contact solar cell structure on a crystalline semiconductor absorber layer, comprising:
forming a passivation and antireflection coating layer on the frontside of a semiconductor absorber;
forming a thicker lightly doped n-type base layer and a thinner heavily doped p-type emitter junction on the backside of said semiconductor absorber; and
forming a backside structure on said thicker lightly doped n-type base layer and said thinner heavily doped p-type emitter junction on the backside of said semiconductor absorber, comprising:
forming a patterned backside dielectric dopant source and passivation structure with base and emitter contact openings;
forming a first interdigitated base and emitter metallization layer comprising a plurality of direct-write printed silicon-containing aluminum fingers directly on said patterned backside dielectric dopant source and passivation structure and contacting said base and emitter regions through said base and emitter contact openings;
forming an electrically insulating backplane layer attached to said solar cell structure on said patterned backside dielectric dopant source and passivation structure and said first patterned interdigitated base and emitter metallization layer, said backplane layer comprising a plurality of via holes landing on said first interdigitated base and emitter metallization layer; and
forming a second interdigitated base and emitter metallization layer on said electrically insulating backplane layer, said second interdigitated base and emitter metallization layer comprising patterned conductor fingers aligned substantially orthogonal to said first interdigitated base and emitter metallization layer.

10. The method for forming an interdigitated back-contact solar cell structure of claim 9, wherein said first interdigitated base and emitter metallization layer is formed by screen printing.

11. The method for forming an interdigitated back-contact solar cell structure of claim 9, wherein said first interdigitated base and emitter metallization layer is formed by inkjet printing.

12. The method for forming an interdigitated back-contact solar cell structure of claim 9, wherein said first interdigitated base and emitter metallization layer is formed by aerosol jet printing.

13. The method for forming an interdigitated back-contact solar cell structure of claim 9, wherein said first interdigitated base and emitter metallization layer is formed by laser transfer printing.

14. The method for forming an interdigitated back-contact solar cell structure of claim 9, wherein said first interdigitated base and emitter metallization layer is formed by direct write printing of said silicon-containing aluminum fingers directly on said patterned backside dielectric dopant source and passivation structure with subsequent thermal treatment of the printed paste to dry paste, burn off solvents, and cure/lower resistivity of the printed metallization structure.

15. The method for forming an interdigitated back-contact solar cell structure of claim 14, wherein said thermal treatment is performed in an in-line belt furnace immediately following the metal paste printing and drying equipment, said furnace being used to complete the solvent burn off and paste cure/resistivity reduction.

16. The method for forming an interdigitated back-contact solar cell structure of claim 9, wherein said plurality of direct-write printed silicon-containing aluminum fingers are formed using an aluminum-silicon alloy paste or ink comprising aluminum-silicon alloy particles shaped substantially as flake-shaped particles.

17. The method for forming an interdigitated back-contact solar cell structure of claim 9, wherein said plurality of direct-write printed silicon-containing aluminum fingers are formed using an aluminum-silicon alloy paste or ink comprising aluminum-silicon alloy particles shaped substantially as spherical-shaped particles.

18. The method for forming an interdigitated back-contact solar cell structure of claim 9, wherein said plurality of direct-write printed silicon-containing aluminum fingers are formed by using an aluminum-silicon alloy paste or ink comprising aluminum-silicon alloy particles shaped substantially as a mixture of flake-shaped particles with spherical-shaped particles.

19. A silicon-containing aluminum alloy for forming an interdigitated back-contact base and emitter contact metallization structure comprising aluminum-silicon alloy particles shaped substantially as a mixture of flake-shaped particles and spherical-shaped particles.

20. The silicon-containing aluminum alloy of claim 19, wherein said alloy is a screen print applicable paste.

21. The silicon-containing aluminum alloy of claim 19, wherein said alloy is an inkjet print applicable ink.

22. The silicon-containing aluminum alloy of claim 19, wherein said alloy is an aerosol jet print applicable ink.
